(19) United States
(12) Patent Application Publication
(10) Pub. No.: US 2024/0256846 A1
(43) Pub. Date: Aug. 1, 2024

(54) MULTIPLEXORS FOR NEURAL NETWORK ARRAY

(71) Applicant: Silicon Storage Technology, Inc, San Jose, CA (US)

(72) Inventors: Hieu Van Tran, San Jose, CA (US); Thuan Vu, San Jose, CA (US); Stanley Hong, San Jose, CA (US); Stephen Trinh, San Jose, CA (US); Anh Ly, San Jose, CA (US)

(21) Appl. No.: 18/135,664

(22) Filed: Apr. 17, 2023

Related U.S. Application Data
(60) Provisional application No. 63/442,724, filed on Feb. 1, 2023.

(51) Int. Cl. G06N 3/065

(52) U.S. Cl. CPC G06N 3/065

(57) ABSTRACT

Numerous examples are disclosed of multiplexors coupled to rows in a neural network array. In one example, a system comprises a neural network array of non-volatile memory cells comprising i rows, where i is a multiple of 2; j row registers, where j<i; j digital-to-analog converters to convert j sets of digital data received from the j row registers into j analog signals; and j multiplexors to route the j analog signals to a subset of the i rows in response to a control signal.

### PRIORITY CLAIM

This application claims priority from U.S. Provisional Patent Application No. 63/442,724, filed on Feb. 1, 2023, and titled, “Input Multiplexors for Neural Network Array,” which is incorporated by reference herein.

### FIELD OF THE INVENTION

Numerous examples are disclosed of multiplexors for a neural network array.

### BACKGROUND OF THE INVENTION

Artificial neural networks mimic biological neural networks (the central nervous systems of animals, in particular the brain) and are used to estimate or approximate functions that can depend on a large number of inputs and are generally unknown. Artificial neural networks generally include layers of interconnected “neurons” which exchange messages between each other.

FIG. 1 illustrates neural network 100, where the circles represent the inputs or layers of neurons. The connections (called synapses) are represented by arrows and have numeric weights that can be tuned based on experience. This makes neural networks adaptive to inputs and capable of learning. Typically, neural networks include a layer of multiple inputs. There are typically one or more intermediate layers of neurons, and an output layer of neurons that provide the output of the neural network. The neurons at each level individually or collectively make a decision based on the received data from the synapses.

One of the major challenges in the development of artificial neural networks for high-performance information processing is a lack of adequate hardware technology. Indeed, practical neural networks rely on a very large number of synapses, enabling high connectivity between neurons, i.e., a very high computational parallelism. In principle, such complexity can be achieved with digital supercomputers or specialized graphics processing unit clusters. However, in addition to high cost, these approaches also suffer from mediocre energy efficiency as compared to biological networks, which consume much less energy primarily because they perform low-precision analog computation. CMOS analog circuits have been used for artificial neural networks, but most CMOS-implemented synapses have been too bulky given the high number of neurons and synapses.

Applicant previously disclosed an artificial (analog) neural network that utilizes one or more non-volatile memory arrays as the synapses in U.S. Patent Application Publication 2017/0337466A1, which is incorporated by reference. The non-volatile memory arrays operate as an analog neural memory and comprise non-volatile memory cells arranged in rows and columns. The neural network includes a first plurality of synapses configured to receive a first plurality of inputs and to generate therefrom a first plurality of outputs, and a first plurality of neurons configured to receive the first plurality of outputs. The first plurality of synapses includes a plurality of memory cells, wherein each of the memory cells includes spaced apart source and drain regions formed in a semiconductor substrate with a channel region extending there between, a floating gate disposed over and insulated from a first portion of the channel region and a non-floating gate disposed over and insulated from a second portion of the channel region. Each of the plurality of memory cells store a weight value corresponding to a number of electrons on the floating gate. The plurality of memory cells multiply the first plurality of inputs by the stored weight values to generate the first plurality of outputs.

### Non-Volatile Memory Cells

Non-volatile memories are known. For example, U.S. Pat. No. 5,029,130 (“the '130 patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE NO 1
Operation of Flash Memory Cell 210 of FIG. 2

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE NO 2
Operation of Flash Memory Cell 310 of FIG. 3

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 V | | 0 | V | 0 V/−8 V | | 8-12 | V | 0 | V |
| Program | 1 | V | 0.1-1 | μA | 8-11 | V | 4.5-9 | V | 4.5-5 | V |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of the FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO 3
Operation of Flash Memory Cell 410 of FIG. 4

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | | |
|---|---|---|---|---|---|---|---|---|
| Program | 1 | V | 0.2-3 | μA | 4.5 | V | 7-9 | V |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE NO 4
Operation of Flash Memory Cell 510 of FIG. 5

| | CG | | BL | | SL | | Substrate | |
|---|---|---|---|---|---|---|---|---|
| Read | 2-5 | V | 0.6-2 | V | 0 | V | 0 | V |
| Erase | −8 to −10 V/0 V | | FLT | | FLT | | 8-10 V/15-20 V | |
| Program | 8-12 | V | 3-5 | V | 0 | V | 0 | V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

In order to utilize the memory arrays comprising one of the types of non-volatile memory cells described above in an artificial neural network, two modifications are made. First, the lines are configured so that each memory cell can be individually programmed, erased, and read without adversely affecting the memory state of other memory cells in the array, as further explained below. Second, continuous (analog) programming of the memory cells is provided.

Specifically, the memory state (i.e., charge on the floating gate) of each memory cell in the array can be continuously changed from a fully erased state to a fully programmed state, and vice-versa, independently and with minimal disturbance of other memory cells. This means the cell storage is effectively analog or at the very least can store one of many discrete values (such as 16 or 64 different values), which allows for very precise and individual tuning of all the memory cells in the memory array, and which makes the memory array ideal for storing and making fine tuning adjustments to the synapsis weights of the neural network.

### Neural Networks Employing Non-Volatile Memory Cell Arrays

FIG. 6 conceptually illustrates a non-limiting example of a neural network 600 utilizing arrays of non-volatile memory cells of the present examples. This example uses the non-volatile memory array neural network for a facial recognition application, but any other appropriate application could be implemented using a non-volatile memory array based neural network.

S0 is the input layer, which for this example is a 32×32 pixel RGB image with 5 bit precision (i.e. three 32×32 pixel arrays, one for each color R, G and B, each pixel being 5 bit precision). The synapses CB1 going from input layer S0 to layer C1 apply different sets of weights in some instances and shared weights in other instances and scan the input image with 3×3 pixel overlapping filters (kernel), shifting the filter by 1 pixel (or more than 1 pixel as dictated by the model). Specifically, values for 9 pixels in a 3×3 portion of the image (i.e., referred to as a filter or kernel) are provided to the synapses CB1, where these 9 input values are multiplied by the appropriate weights and, after summing the outputs of that multiplication, a single output value is determined and provided by a first synapse of CB1 for generating a pixel of one of the feature maps of layer C1. The 3×3 filter is then shifted one pixel to the right within input layer S0 (i.e., adding the column of three pixels on the right, and dropping the column of three pixels on the left), whereby the 9 pixel values in this newly positioned filter are provided to the synapses CB1, where they are multiplied by the same weights and a second single output value is determined by the associated synapse. This process is continued until the 3×3 filter scans across the entire 32×32 pixel image of input layer S0, for all three colors and for all bits (precision values). The process is then repeated using different sets of weights to generate a different feature map of layer C1, until all the features maps of layer C1 have been calculated.

In layer C1, in the present example, there are 16 feature maps, with 30×30 pixels each. Each pixel is a new feature pixel extracted from multiplying the inputs and kernel, and therefore each feature map is a two-dimensional array, and thus in this example layer C1 constitutes 16 layers of two-dimensional arrays (keeping in mind that the layers and arrays referenced herein are logical relationships, not necessarily physical relationships—i.e., the arrays are not necessarily oriented in physical two-dimensional arrays). Each of the 16 feature maps in layer C1 is generated by one of sixteen different sets of synapse weights applied to the filter scans. The C1 feature maps could all be directed to different aspects of the same image feature, such as boundary identification. For example, the first map (generated using a first weight set, shared for all scans used to generate this first map) could identify circular edges, the second map (generated using a second weight set different from the first weight set) could identify rectangular edges, or the aspect ratio of certain features, and so on.

An activation function P1 (pooling) is applied before going from layer C1 to layer S1, which pools values from consecutive, non-overlapping 2×2 regions in each feature map. The purpose of the pooling function P1 is to average out the nearby location (or a max function can also be used), to reduce the dependence of the edge location for example and to reduce the data size before going to the next stage. At layer S1, there are 16 15×15 feature maps (i.e., sixteen different arrays of 15×15 pixels each). The synapses CB2 going from layer S1 to layer C2 scan maps in layer S1 with 4×4 filters, with a filter shift of 1 pixel. At layer C2, there are 22 12×12 feature maps. An activation function P2 (pooling) is applied before going from layer C2 to layer S2, which pools values from consecutive non-overlapping 2×2 regions in each feature map. At layer S2, there are 22 6×6 feature maps. An activation function (pooling) is applied at the synapses CB3 going from layer S2 to layer C3, where every neuron in layer C3 connects to every map in layer S2 via a respective synapse of CB3. At layer C3, there are 64 neurons. The synapses CB4 going from layer C3 to the output layer S3 fully connects C3 to S3, i.e. every neuron in layer C3 is connected to every neuron in layer S3. The output at S3 includes 10 neurons, where the highest output neuron determines the class. This output could, for example, be indicative of an identification or classification of the contents of the original image.

Each layer of synapses is implemented using an array, or a portion of an array, of non-volatile memory cells.

FIG. 7 is a block diagram of a VMM system 32 that can be used for that purpose. Vector-by-matrix multiplication (VMM) system 32 includes non-volatile memory cells and is utilized as the synapses (such as CB1, CB2, CB3, and CB4 in FIG. 6) between one layer and the next layer. Specifically, VMM system 32 includes VMM array 33 (which can also be referred to as neural network array 33), which is an array of non-volatile memory cells, erase gate and word line gate decoder 34, control gate decoder 35, bit line decoder 36 and source line decoder 37, which decode the respective inputs for the non-volatile memory cell array 33. Input to VMM array 33 can be from the erase gate and wordline gate decoder 34 or from the control gate decoder 35. Source line decoder 37 in this example also decodes the output of VMM array 33. Alternatively, bit line decoder 36 can decode the output of VMM array 33.

VMM array 33 serves two purposes. First, it stores the weights that will be used by the VMM system 32. Second, VMM array 33 effectively multiplies the inputs by the weights stored in VMM array 33 and adds them up per output line (source line or bit line) to produce the output, which will be the input to the next layer or input to the final layer. By performing the multiplication and addition function, VMM array 33 negates the need for separate multiplication and addition logic circuits and is also power efficient due to its in-situ memory computation.

The output of VMM array 33 is supplied to a differential summer (such as a summing op-amp or a summing current mirror) 38, which sums up the outputs of the VMM array 33 to create a single value for that convolution. The differential summer 38 is arranged to perform summation of positive weight and negative weight.

The summed-up output values of differential summer 38 are then supplied to an activation function block 39, which rectifies the output. The activation function block 39 may provide sigmoid, tanh, or ReLU functions. The rectified output values of activation function block 39 become an element of a feature map as the next layer (e.g., C1 in FIG. 6), and are then applied to the next synapse to produce the next feature map layer or final layer. Therefore, in this example, VMM array 33 constitutes a plurality of synapses (which receive their inputs from the prior layer of neurons or from an input layer such as an image database), and summing op-amp 38 and activation function block 39 constitute a plurality of neurons.

The input to VMM system 32 in FIG. 7 (WLx, EGx, CGx, and optionally BLx and SLx) can be analog level, binary level, or digital bits (in which case a DAC is provided to convert digital bits to appropriate input analog level) and the output can be analog level, binary level, or digital bits (in which case an output ADC is provided to convert output analog level into digital bits).

FIG. 8 depicts neural network 800. Neural network 800 comprises numerous layers formed of VMM systems 32, here labeled as VMM systems 32a, 32b, 32c, 32d, and 32c. As shown in FIG. 8, the input, denoted Inputx, is converted from digital to analog by a digital-to-analog converter 31 and provided to input VMM system 32a. The converted analog inputs could be voltage or current. The input D/A conversion for the first layer could be done by using a function or a LUT (look up table) that maps the inputs Inputx to appropriate analog levels for the matrix multiplier of input VMM system 32a. The input conversion could also be done by an analog to analog (A/A) converter to convert an external analog input to a mapped analog input to the input VMM system 32a.

The output generated by input VMM system 32a is provided as an input to the next VMM system (hidden level 1) 32b, which in turn generates an output that is provided as an input to the next VMM system (hidden level 2) 32c, and so on. The various layers of VMM system 32 function as different layers of synapses and neurons of a convolutional neural network (CNN). Each VMM system 32a, 32b, 32c, 32d, and 32e can comprise a stand-alone, physical non-volatile memory array, or multiple VMM systems could utilize different portions of the same physical non-volatile memory array, or multiple VMM systems could utilize overlapping portions of the same physical non-volatile memory array. The example shown in FIG. 8 contains five layers (32a,32b,32c,32d,32e): one input layer (32a), two hidden layers (32b,32c), and two fully connected layers (32d,32e). One of ordinary skill in the art will appreciate that this is merely an example and that a system instead could comprise more than two hidden layers and more than two fully connected layers.

### Vector-by-Matrix Multiplication (VMM) Arrays

FIG. 9 depicts VMM array 900, which is particularly suited for memory cells 310 as shown in FIG. 3 and is utilized as the synapses and parts of neurons between an input layer and the next layer. (A person of ordinary skill in the art will understand that a VMM array can also be referred to as a neural network array.) VMM array 900 comprises memory array 901 of non-volatile memory cells and reference array 902 (at the top of the array) of non-volatile reference memory cells. Alternatively, another reference array can be placed at the bottom.

In VMM array 900, control gate lines, such as control gate line 903, run in a vertical direction (hence reference array 902 in the row direction is orthogonal to control gate line 903), and erase gate lines, such as erase gate line 904, run in a horizontal direction. Here, the inputs to VMM array 900 are provided on the control gate lines (CG0, CG1, CG2, CG3), and the output of VMM array 900 emerges on the source lines (SL0, SL1). In one example, only even rows are used, and in another example, only odd rows are used. The current placed on each source line (SL0, SL1, respectively) performs a summing function of all the currents from the memory cells connected to that particular source line.

As described herein for neural networks, the non-volatile memory cells of VMM array 900, i.e., the memory cells 310 of VMM array 900, may be configured to operate in a sub-threshold region.

The non-volatile reference memory cells and the non-volatile memory cells described herein are biased in weak inversion (sub threshold region):

$$Ids = Io * {e}^{* Vg - Vth ) / nVt} = w * Io * {e}^{( Vg ) / nVt} ,$$

$$where w = {e}^{( - V th ) / nVt}$$

where Ids is the drain to source current; Vg is gate voltage on the memory cell; Vth is threshold voltage of the memory cell; Vt is thermal voltage=k*T/q with k being the Boltzmann constant, T the temperature in Kelvin, and q the electronic charge; n is a slope factor=1+(Cdep/Cox) with Cdep=capacitance of the depletion layer, and Cox capacitance of the gate oxide layer; Io is the memory cell current at gate voltage equal to threshold voltage, Io is proportional to (Wt/L)*u*Cox*(n−1)*Vt² where u is carrier mobility and Wt and L are width and length, respectively, of the memory cell.

For an I-to-V log converter using a memory cell (such as a reference memory cell or a peripheral memory cell) or a transistor to convert input current into an input voltage:

$$Vg = n * Vt * log [ Ids / wp * Io ]$$

where, wp is w of a reference or peripheral memory cell.

For a memory array used as a vector matrix multiplier VMM array with the current input, the output current is:

$$Iout = wa * Io * {e}^{( Vg ) / nVt} , namely ,$$

$$Iout = ( wa / wp ) * Iin = W * Iin$$

$$W = {e}^{( V thp - Vtha ) / nVt}$$

Here, wa=w of each memory cell in the memory array.
Vthp is effective threshold voltage of the peripheral memory cell and Vtha is effective threshold voltage of the main (data) memory cell. Note that the threshold voltage of a transistor is a function of substrate body bias voltage and the substrate body bias voltage, denoted Vsb, can be modulated to compensate for various conditions, on such temperature. The threshold voltage Vth can be expressed as:

$$Vth = Vth 0 + gamma ( SQRT \vert 2 * φ F ) - SQRT \vert 2 * φ F \vert )$$

where Vth0 is threshold voltage with zero substrate bias, φF is a surface potential, and gamma is a body effect parameter.

A wordline or control gate can be used as the input for the memory cell for the input voltage.

Alternatively, the flash memory cells of VMM arrays described herein can be configured to operate in the linear region:

$$Ids = beta * ( Vgs - Vth ) * Vds ; beta = u * Cox * Wt / L$$

$$W = α ( Vgs - Vth )$$

meaning weight W in the linear region is proportional to (Vgs−Vth)

A wordline or control gate or bitline or sourceline can be used as the input for the memory cell operated in the linear region. The bitline or sourceline can be used as the output for the memory cell.

For an I-to-V linear converter, a memory cell (such as a reference memory cell or a peripheral memory cell) or a transistor operating in the linear region can be used to linearly convert an input/output current into an input/output voltage.

Alternatively, the memory cells of VMM arrays described herein can be configured to operate in the saturation region:

$$Ids = 1 / 2 * beta * {( Vgs - Vth )}^{2} ; beta = u * Cox * Wt / L$$

$$W {α ( Vgs - Vth )}^{2} , meaning weight W is proportional {to ( Vgs - Vth )}^{2}$$

A wordline, control gate, or erase gate can be used as the input for the memory cell operated in the saturation region. The bitline or sourceline can be used as the output for the output neuron.

Alternatively, the memory cells of VMM arrays described herein can be used in all regions or a combination thereof (sub threshold, linear, or saturation) for each layer or multi layers of a neural network.

Other examples for VMM system 32 of FIG. 7 are described in U.S. Pat. No. 10,748,630, which is incorporated by reference herein. As described in that application. a sourceline or a bitline can be used as the neuron output (current summation output).

FIG. 10 depicts VMM array 1000, which is particularly suited for memory cells 210 as shown in FIG. 2 and is utilized as the synapses between an input layer and the next layer. VMM array 1000 comprises a memory array 1003 of non-volatile memory cells, reference array 1001 of first non-volatile reference memory cells, and reference array 1002 of second non-volatile reference memory cells. Reference arrays 1001 and 1002, arranged in the column direction of the array, serve to convert current inputs flowing into terminals BLR0, BLR1, BLR2, and BLR3 into voltage inputs WL0, WL1, WL2, and WL3. In effect, the first and second non-volatile reference memory cells are diode-connected through multiplexors 1014 (only partially depicted) with current inputs flowing into them. The reference cells are tuned (e.g., programmed) to target reference levels. The target reference levels are provided by a reference mini-array matrix (not shown).

Memory array 1003 serves two purposes. First, it stores the weights that will be used by the VMM array 1000 on respective memory cells thereof. Second, memory array 1003 effectively multiplies the inputs (i.e. current inputs provided in terminals BLR0, BLR1, BLR2, and BLR3, which reference arrays 1001 and 1002 convert into the input voltages to supply to wordlines WL0, WL1, WL2, and WL3) by the weights stored in the memory array 1003 and then adds all the results (memory cell currents) to produce the output on the respective bit lines (BL0-BLN), which will be the input to the next layer or input to the final layer. By performing the multiplication and addition function, memory array 1003 negates the need for separate multiplication and addition logic circuits and is also power efficient. Here, the voltage inputs are provided on the word lines WL0, WL1, WL2, and WL3, and the output emerges on the respective bit lines BL0-BLN during a read (inference) operation. The current placed on each of the bit lines BL0-BLN performs a summing function of the currents from all non-volatile memory cells connected to that particular bitline.

Table No. 5 depicts operating voltages and currents for VMM array 1000. The columns in the table indicate the voltages placed on word lines for selected cells, word lines for unselected cells, bit lines for selected cells, bit lines for unselected cells, source lines for selected cells, and source lines for unselected cells. The rows indicate the operations of read, erase, and program.

TABLE NO. 5
Operation of VMM Array 1000 of FIG. 10:

| | WL | | WL -unsel | BL | | BL -unsel | SL | SL -unsel | |
|---|---|---|---|---|---|---|---|---|---|
| Read | 1-3.5 | V | −0.5 V/0 V | 0.6-2 V | | 0.6 V-2 V/0 V | 0 V | 0 | V |
| | | | | (Ineuron) | | | | | |
| Erase | ~5-13 | V | 0 V | 0 | V | 0 V | 0 V | 0 | V |
| Program | 1-2 | V | −0.5 V/0 V | 0.1-3 | uA | Vinh ~2.5 V | 4-10 V | 0-1 | V/FLT |

FIG. 11 depicts VMM array 1100, which is particularly suited for memory cells 210 as shown in FIG. 2 and is utilized as the synapses and parts of neurons between an input layer and the next layer. VMM array 1100 comprises a memory array 1103 of non-volatile memory cells, reference array 1101 of first non-volatile reference memory cells, and reference array 1102 of second non-volatile reference memory cells. Reference arrays 1101 and 1102 run in row direction of the VMM array 1100. VMM array is similar to VMM 1000 except that in VMM array 1100, the word lines run in the vertical direction. Here, the inputs are provided on the word lines (WLA0, WLB0, WLA1, WLB2, WLA2, WLB2, WLA3, WLB3), and the output emerges on the source line (SL0, SL1) during a read operation. The current placed on each source line performs a summing function of all the currents from the memory cells connected to that particular source line.

Table No. 6 depicts operating voltages and currents for VMM array 1100. The columns in the table indicate the voltages placed on word lines for selected cells, word lines for unselected cells, bit lines for selected cells, bit lines for unselected cells, source lines for selected cells, and source lines for unselected cells. The rows indicate the operations of read, erase, and program.

TABLE NO. 6
Operation of VMM Array 1100 of FIG. 11

| | WL | | WL -unsel | BL | | BL -unsel | SL | | SL -unsel | |
|---|---|---|---|---|---|---|---|---|---|---|
| Read | 1-3.5 | V | −0.5 V/0 V | 0.6-2 | V | 0.6 V-2 V/0 V | ~0.3-1 V | | 0 | V |
| | | | | | | | (Ineuron) | | | |
| Erase | ~5-13 | V | 0 V | 0 | V | 0 V | 0 | V | SL-inhibit | |
| | | | | | | | | | (~4-8 V) | |
| Program | 1-2 | V | −0.5 V/0 V | 0.1-3 | uA | Vinh ~2.5 V | 4-10 | V | 0-1 | V/FLT |

FIG. 12 depicts VMM array 1200, which is particularly suited for memory cells 310 as shown in FIG. 3 and is utilized as the synapses and parts of neurons between an input layer and the next layer. VMM array 1200 comprises a memory array 1203 of non-volatile memory cells, reference array 1201 of first non-volatile reference memory cells, and reference array 1202 of second non-volatile reference memory cells. Reference arrays 1201 and 1202 serve to convert current inputs flowing into terminals BLR0, BLR1, BLR2, and BLR3 into voltage inputs CG0, CG1, CG2, and CG3. In effect, the first and second non-volatile reference memory cells are diode-connected through multiplexors 1212 (only partially shown) with current inputs flowing into them through BLR0, BLR1, BLR2, and BLR3. Multiplexors 1212 each include a respective multiplexor 1205 and a cascoding transistor 1204 to ensure a constant voltage on the bitline (such as BLR0) of each of the first and second non-volatile reference memory cells during a read operation. The reference cells are tuned to target reference levels.

Memory array 1203 serves two purposes. First, it stores the weights that will be used by the VMM array 1200. Second, memory array 1203 effectively multiplies the inputs (current inputs provided to terminals BLR0, BLR1, BLR2, and BLR3, for which reference arrays 1201 and 1202 convert these current inputs into the input voltages to supply to the control gates (CG0, CG1, CG2, and CG3) by the weights stored in the memory array and then add all the results (cell currents) to produce the output, which appears on BL0-BLN, and will be the input to the next layer or input to the final layer. By performing the multiplication and addition function, the memory array negates the need for separate multiplication and addition logic circuits and is also power efficient. Here, the inputs are provided on the control gate lines (CG0, CG1, CG2, and CG3), and the output emerges on the bit lines (BL0-BLN) during a read operation. The current placed on each bitline performs a summing function of all the currents from the memory cells connected to that particular bitline.

VMM array 1200 implements uni-directional tuning for non-volatile memory cells in memory array 1203. That is, each non-volatile memory cell is erased and then partially programmed until the desired charge on the floating gate is reached. If too much charge is placed on the floating gate (such that the wrong value is stored in the cell), the cell is erased, and the sequence of partial programming operations starts over. As shown, two rows sharing the same erase gate (such as EG0 or EG1) are erased together (which is known as a page erase), and thereafter, each cell is partially programmed until the desired charge on the floating gate is reached.

Table No. 7 depicts operating voltages and currents for VMM array 1200. The columns in the table indicate the voltages placed on word lines for selected cells, word lines for unselected cells, bit lines for selected cells, bit lines for unselected cells, control gates for selected cells, control gates for unselected cells in the same sector as the selected cells, control gates for unselected cells in a different sector than the selected cells, erase gates for selected cells, erase gates for unselected cells, source lines for selected cells, and source lines for unselected cells. The rows indicate the operations of read, erase, and program.

TABLE NO. 7
Operation of VMM Array 1200 of FIG. 12

| | | | WL - | | | BL - | | | CG - unsel | CG - | | EG - | | | SL - |
|---|---|---|---|---|---|---|---|---|---|---|---|---|---|---|---|
| | WL | | unsel | BL | | unsel | CG | | same sector | unsel | EG | unsel | SL | | unsel |
| Read | 1.0-2 | V | −0.5 V/ 0 V | 0.6-2 V | | 0 V | 0-2.6 | V | 0-2.6 V | 0-2.6 V | 0-2.6 V | 0-2.6 V | 0 | V | 0 V |
| | | | | (Ineuron) | | | | | | | | | | | |
| Erase | 0 | V | 0 V | 0 | V | 0 V | 0 | V | 0-2.6 V | 0-2.6 V | 5-12 V | 0-2.6 V | 0 | V | 0 V |
| Program | 0.7-1 | V | −0.5 V/0 V | 0.1-1 | uA | Vinh | 4-11 | V | 0-2.6 V | 0-2.6 V | 4.5-5 V | 0-2.6 V | 4.5-5 | V | 0-1 V |
| | | | | | | (1-2 V) | | | | | | | | | |

FIG. 13 depicts VMM array 1300, which is particularly suited for memory cells 310 as shown in FIG. 3 and is utilized as the synapses and parts of neurons between an input layer and the next layer. VMM array 1300 comprises a memory array 1303 of non-volatile memory cells, reference array 1301 or first non-volatile reference memory cells, and reference array 1302 of second non-volatile reference memory cells. EG lines EGR0, EG0, EG1 and EGR1 are run vertically while CG lines CG0, CG1, CG2 and CG3 and SL lines WL0, WL1, WL2 and WL3 are run horizontally. VMM array 1300 is similar to VMM array 1400, except that VMM array 1300 implements bi-directional tuning, where each individual cell can be completely erased, partially programmed, and partially erased as needed to reach the desired amount of charge on the floating gate due to the use of separate EG lines. As shown, reference arrays 1301 and 1302 convert input current in the terminal BLR0, BLR1, BLR2, and BLR3 into control gate voltages CG0, CG1, CG2, and CG3 (through the action of diode-connected reference cells through multiplexors 1314) to be applied to the memory cells in the row direction. The current output (neuron) is in the bit lines BL0-BLN, where each bit line sums all currents from the non-volatile memory cells connected to that particular bitline.

Table No. 8 depicts operating voltages and currents for VMM array 1300. The columns in the table indicate the voltages placed on word lines for selected cells, word lines for unselected cells, bit lines for selected cells, bit lines for unselected cells, control gates for selected cells, control gates for unselected cells in the same sector as the selected cells, control gates for unselected cells in a different sector than the selected cells, erase gates for selected cells, erase gates for unselected cells, source lines for selected cells, and source lines for unselected cells. The rows indicate the operations of read, erase, and program.

TABLE NO. 8
Operation of VMM Array 1300 of FIG. 13

| | | | WL - | | | BL - | | | CG - unsel | CG - | | EG - | | | SL - |
|---|---|---|---|---|---|---|---|---|---|---|---|---|---|---|---|
| | WL | | unsel | BL | | unsel | CG | | same sector | unsel | EG | unsel | SL | | unsel |
| Read | 1.0-2 | V | −0.5 V/0 V | 0.6-2 V | | 0 V | 0-2.6 | V | 0-2.6 V | 0-2.6 V | 0-2.6 V | 0-2.6 V | 0 | V | 0 V |
| | | | | (Ineuron) | | | | | | | | | | | |
| Erase | 0 | V | 0 V | 0 | V | 0 V | 0 | V | 4-9 V | 0-2.6 V | 5-12 V | 0-2.6 V | 0 | V | 0 V |
| Program | 0.7-1 | V | −0.5 V/0 V | 0.1-1 | uA | Vinh | 4-11 | V | 0-2.6 V | 0-2.6 V | 4.5-5 V | 0-2.6 V | 4.5-5 | V | 0-1 V |
| | | | | | | (1-2 V) | | | | | | | | | |

FIG. 14 depicts VMM array 1400, which is particularly suited for memory cells 210 as shown in FIG. 2 and is utilized as the synapses and parts of neurons between an input layer and the next layer. In VMM array 1400, the inputs INPUT₀, . . . , INPUT_{N} are received on bit lines BL₀, . . . BL_{N}, respectively, and the outputs OUTPUT₁, OUTPUT₂, OUTPUT₃, and OUTPUT₄ are generated on source lines SL₀, SL₁, SL₂, and SL₃, respectively.

FIG. 15 depicts neuron VMM array 1500, which is particularly suited for memory cells 210 as shown in FIG. 2 and is utilized as the synapses and parts of neurons between an input layer and the next layer. In this example, the inputs INPUT₀, INPUT₁, INPUT₂, and INPUT₃ are received on source lines SL₀, SL₁, SL₂, and SL₃, respectively, and the outputs OUTPUT₀, . . . OUTPUT_{N} are generated on bit lines BL₀, . . . , BL_{N}.

FIG. 16 depicts VMM array 1600, which is particularly suited for memory cells 210 as shown in FIG. 2 and is utilized as the synapses and parts of neurons between an input layer and the next layer. In this example, the inputs INPUT_{0,} . . . , INPUT_{M} are received on word lines WL₀, . . . , WL_{M}, respectively, and the outputs OUTPUT₀, . . . OUTPUT_{N} are generated on bit lines BL₀, . . . , BL_{N}.

FIG. 17 depicts VMM array 1700, which is particularly suited for memory cells 310 as shown in FIG. 3 and is utilized as the synapses and parts of neurons between an input layer and the next layer. In this example, the inputs INPUT₀, . . . , INPUT_{M} are received on word lines WL₀, . . . , WL_{M}, respectively, and the outputs OUTPUT₀, . . . OUTPUT_{N} are generated on bit lines BL₀, . . . , BL_{N}.

FIG. 18 depicts VMM array 1800, which is particularly suited for memory cells 410 as shown in FIG. 4 and is utilized as the synapses and parts of neurons between an input layer and the next layer. In this example, the inputs INPUT_{0,} . . . , INPUT_{N} are received on vertical control gate lines CG₀, . . . , CG_{N}, respectively, and the outputs OUTPUT₁ and OUTPUT₂ are generated on source lines SL₀ and SL₁.

FIG. 19 depicts VMM array 1900, which is particularly suited for memory cells 410 as shown in FIG. 4 and is utilized as the synapses and parts of neurons between an input layer and the next layer. In this example, the inputs INPUT_{0,} . . . , INPUT_{N} are received on the gates of bit line control gates 1901-1, 1901-2, . . . , 1901-(N−1), and 1901-N, respectively, which are coupled to bit lines BL₀, . . . , BL_{N}, respectively. Example outputs OUTPUT, and OUTPUT₂ are generated on source lines SL₀ and SL₁.

FIG. 20 depicts VMM array 2000, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT_{0,} . . . , INPUT_{M} are received on word lines WL₀, . . . , WL_{M}, and the outputs OUTPUT_{0,} . . . , OUTPUT_{N} are generated on bit lines BL₀, . . . , BL_{N}, respectively.

FIG. 21 depicts VMM array 2100, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT_{0,} . . . , INPUT_{M} are received on control gate lines CG₀, . . . , CG_{M}. Outputs OUTPUT_{0,} . . . , OUTPUT_{N} are generated on vertical source lines SL₀, . . . , SL_{N}, respectively, where each source line SLᵢ is coupled to the source lines of all memory cells in column i.

FIG. 22 depicts VMM array 2200, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT_{0,} . . . , INPUT_{M} are received on control gate lines CG₀, . . . , CG_{M}. Outputs OUTPUT_{0,} . . . , OUTPUT_{N} are generated on vertical bit lines BL₀, . . . , BL_{N}, respectively, where each bit line BLᵢ is coupled to the bit lines of all memory cells in column i.

The input to the VMM arrays can be an analog level, a binary level, a pulse, a time modulated pulse, or digital bits (in this case a DAC is used to convert digital bits to appropriate input analog level) and the output can be an analog level, a binary level, a timing pulse, pulses, or digital bits (in this case an output ADC is used to convert output analog level into digital bits).

In general, for each memory cell in a VMM array, each weight W can be implemented by a single memory cell or by a differential cell or by two blend memory cells (average of 2 cells). In the differential cell case, two memory cells are used to implement a weight W as a differential weight (W=W+−W−). In the two blend memory cells, two memory cells are used to implement a weight W as an average of two cells.

FIG. 23 depicts VMM system 2300. In some examples, the weights, W, stored in a VMM array are stored as differential pairs, W+ (positive weight) and W− (negative weight), where W=(W+)−(W−). In VMM system 2300, half of the bit lines are designated as W+ lines, that is, bit lines connecting to memory cells that will store positive weights W+, and the other half of the bit lines are designated as W− lines, that is, bit lines connecting to memory cells implementing negative weights W−. The W− lines are interspersed among the W+ lines in an alternating fashion. The subtraction operation is performed by a summation circuit that receives current from a W+ line and a W− line, such as summation circuits 2301 and 2302. The output of a W+ line and the output of a W− line are combined together to give effectively W=W+−W− for each pair of (W+, W−) cells for all pairs of (W+, W−) lines. While the above has been described in relation to W− lines interspersed among the W+ lines in an alternating fashion, in other examples W+ lines and W− lines can be arbitrarily located anywhere in the array.

FIG. 24 depicts VMM system 2400. In VMM system 2400, positive weights W+ are implemented in first array 2411 and negative weights W− are implemented in a second array 2412, second array 2412 separate from the first array, and the resulting weights are appropriately combined together by summation circuits 2413.

FIG. 25 depicts VMM system 2500. The weights, W, stored in a VMM array are stored as differential pairs, W+(positive weight) and W− (negative weight), where W=(W+)−(W−). VMM system 2500 comprises array 2501 and array 2502. Half of the bit lines in each of array 2501 and 2502 are designated as W+ lines, that is, bit lines connecting to memory cells that will store positive weights W+, and the other half of the bit lines in each of array 2501 and 2502 are designated as W− lines, that is, bit lines connecting to memory cells implementing negative weights W−. The W− lines are interspersed among the W+ lines in an alternating fashion. The subtraction operation is performed by a summation circuit that receives current from a W+ line and a W− line, such as summation circuits 2503, 2504, 2505, and 2506. The output of a W+ line and the output of a W− line from each array 2501, 2502 are respectively combined together to give effectively W=W+−W− for each pair of (W+, W−) cells for all pairs of (W+, W−) lines. In addition, the W values from each array 2501 and 2502 can be further combined through summation circuits 2507 and 2508, such that each W value is the result of a W value from array 2501 minus a W value from array 2502, meaning that the end result from summation circuits 2507 and 2508 is a differential value of two differential values.

Each non-volatile memory cells used in the analog neural memory system is to be erased and programmed to hold a very specific and precise amount of charge, i.e., the number of electrons, in the floating gate. For example, each floating gate should hold one of N different values, where N is the number of different weights that can be indicated by each cell. Examples of N include 16, 32, 64, 128, and 256.

Prior art systems have encountered significant leakage within VMM arrays. Also, the circuitry outside the VMM array in a VMM system take a significant amount of space in the semiconductor die. What is needed is VMM system comprising circuitry that uses less space and VMM arrays that result in less leakage compared to prior art systems.

### SUMMARY OF THE INVENTION

Numerous examples are disclosed of multiplexors for use with a neural network array.

### BRIEF DESCRIPTION OF THE DRAWINGS

FIG. 1 depicts an example neural network.

FIG. 2 depicts a split gate flash memory cell.

FIG. 3 depicts another split gate flash memory cell.

FIG. 4 depicts another split gate flash memory cell.

FIG. 5 depicts another split gate flash memory cell.

FIG. 6 depicts an example neural network.

FIG. 7 depicts an example VMM system.

FIG. 8 depicts an example neural network.

FIG. 9 depicts another example of a VMM array.

FIG. 10 depicts another example of a VMM array.

FIG. 11 depicts another example of a VMM array.

FIG. 12 depicts another example of a VMM array.

FIG. 13 depicts another example of a VMM array.

FIG. 14 depicts another example of a VMM array

FIG. 15 depicts another example of a VMM array.

FIG. 16 depicts another example of a VMM array.

FIG. 17 depicts another example of a VMM array.

FIG. 18 depicts another example of a VMM array.

FIG. 19 depicts another example of a VMM array.

FIG. 20 depicts another example of a VMM array.

FIG. 21 depicts another example of a VMM array.

FIG. 22 depicts another example of a VMM array.

FIG. 23 depicts another example of a VMM system.

FIG. 24 depicts another example of a VMM system.

FIG. 25 depicts another example of a VMM system.

FIG. 26 depicts a VMM system.

FIG. 27A depicts a selected memory cell.

FIGS. 27B, 27C, and 27D depict an unselected memory cell.

FIG. 28 depicts a VMM system comprising source line pull down circuitry.

FIG. 29 depicts a VMM system comprising an input block coupled to a neural network array.

FIG. 30 depicts a VMM system comprising an input block coupled to a neural network array.

FIG. 31 depicts a VMM system comprising an input block coupled to a neural network array.

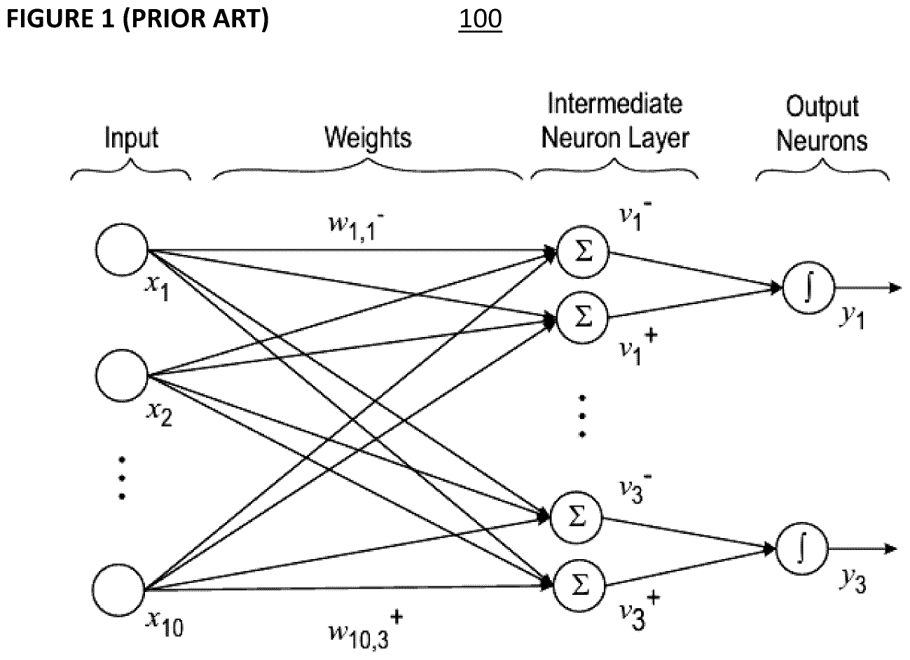

### DETAILED DESCRIPTION OF THE INVENTION

### VMM System Architecture

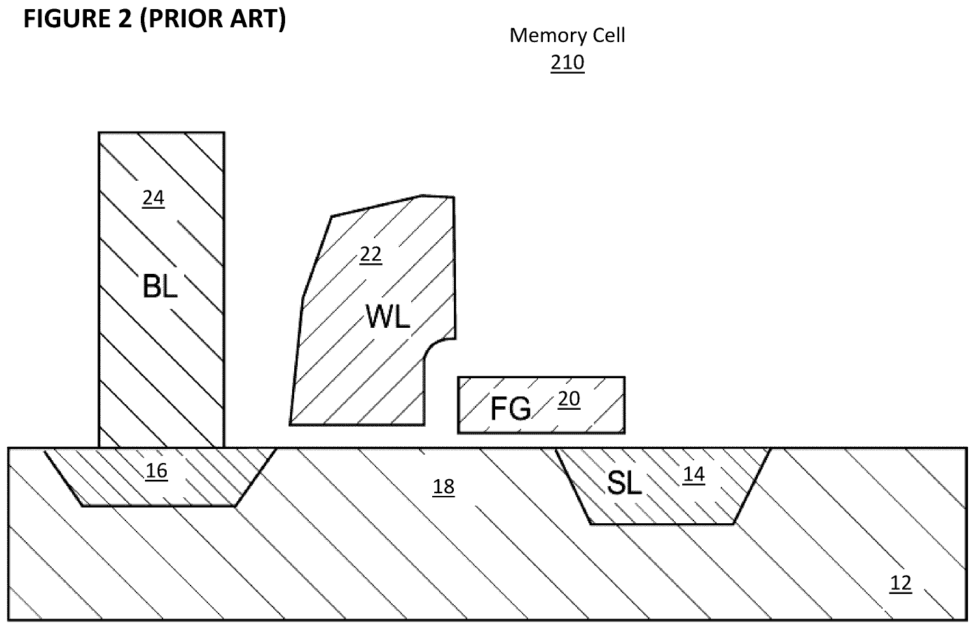

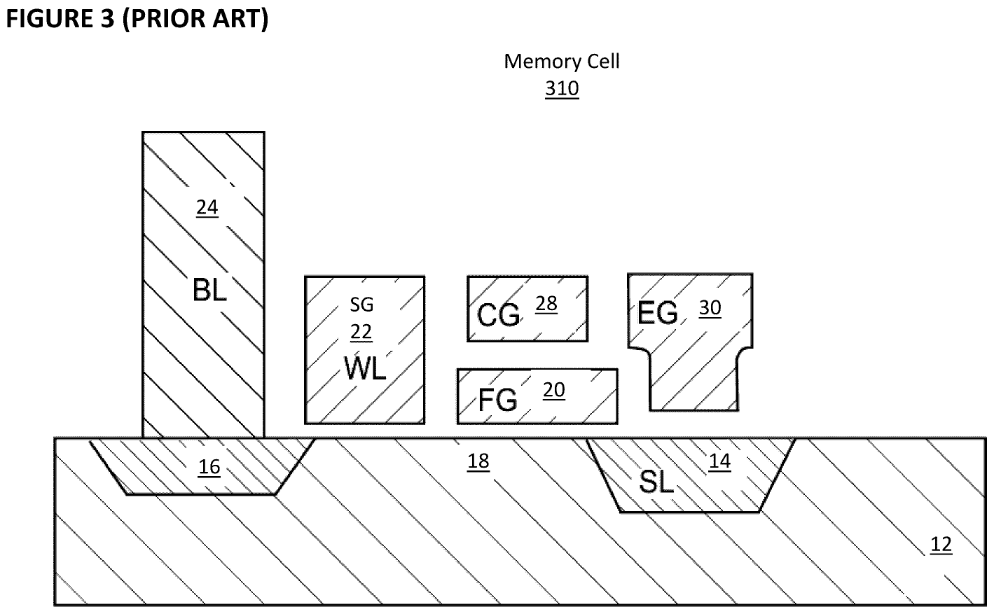

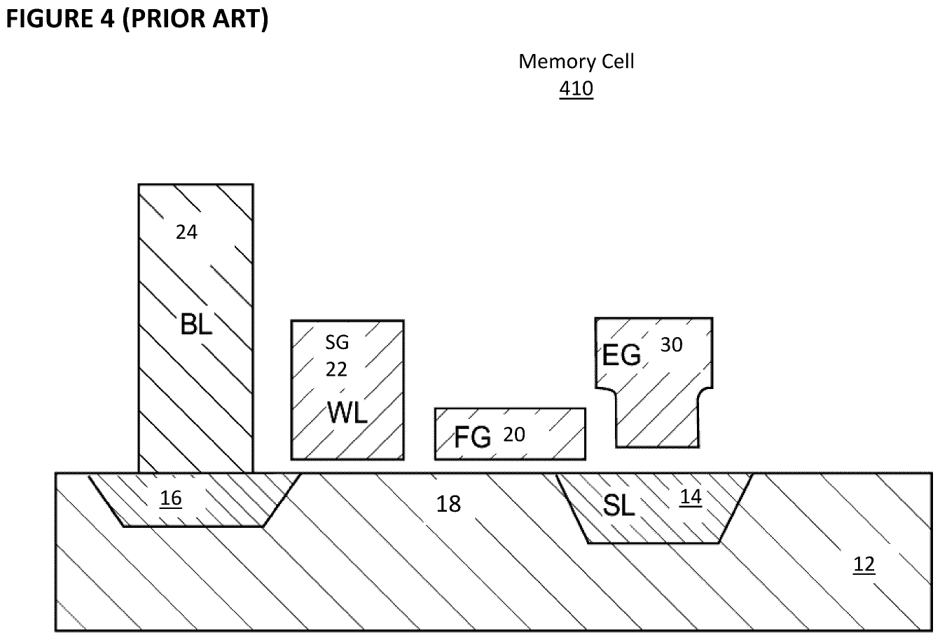

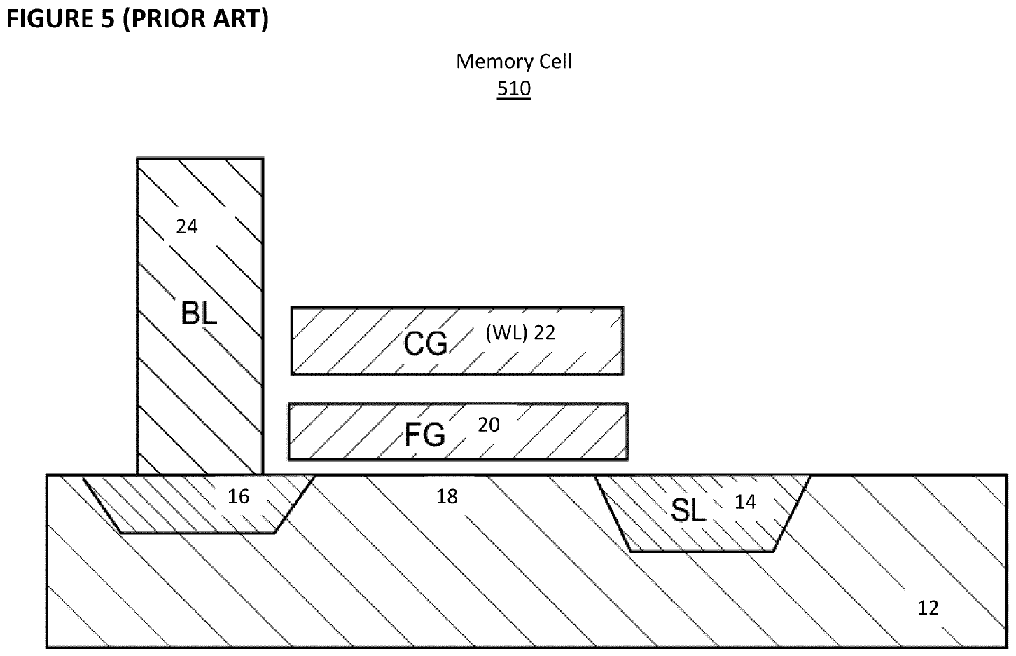

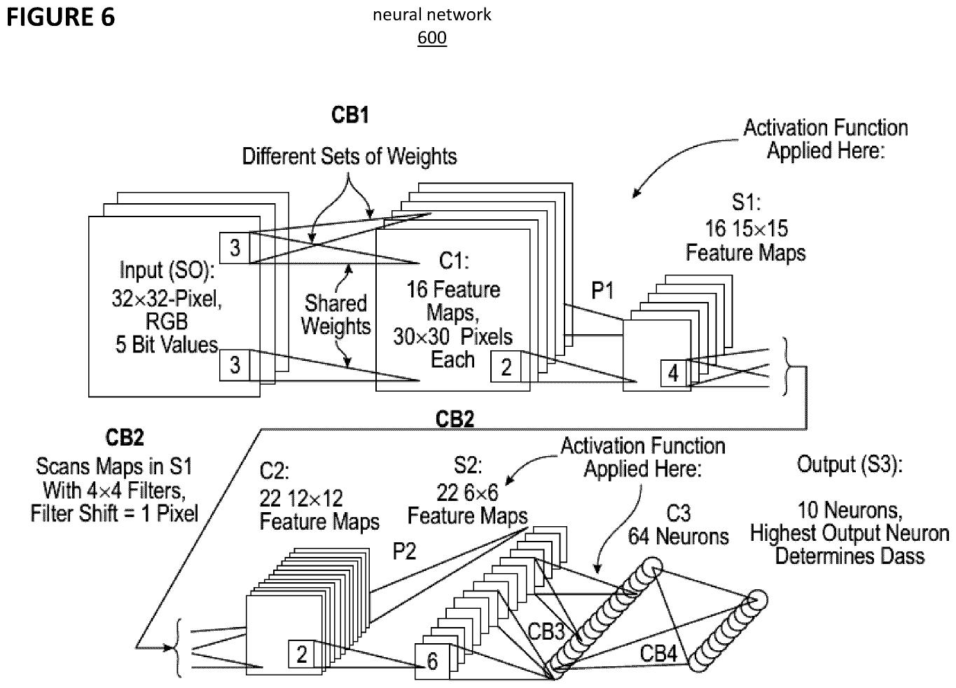

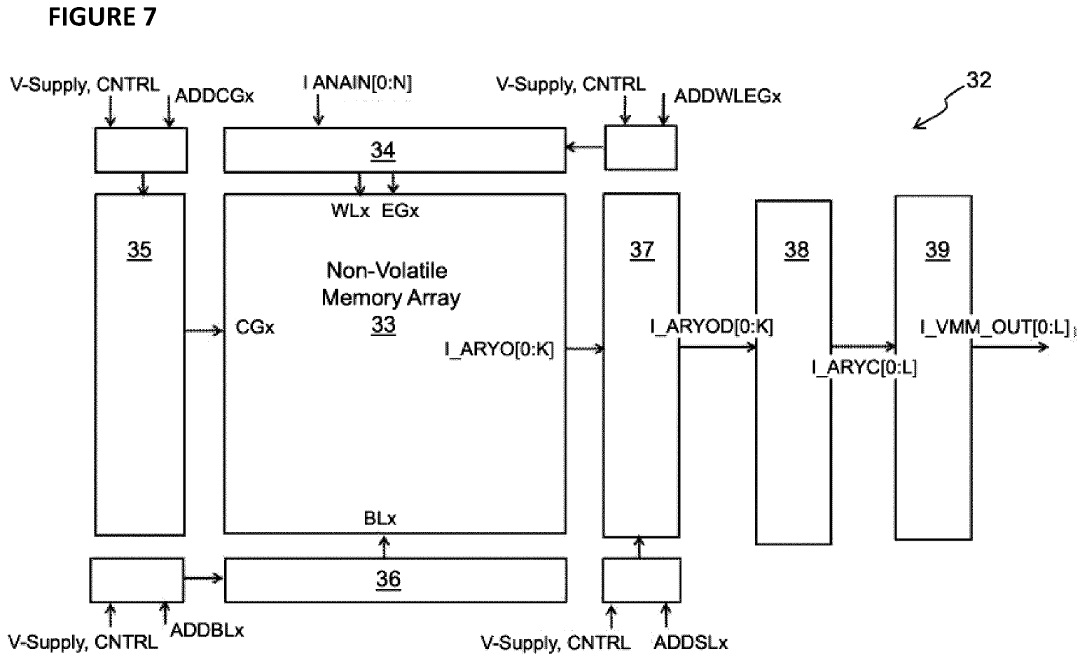

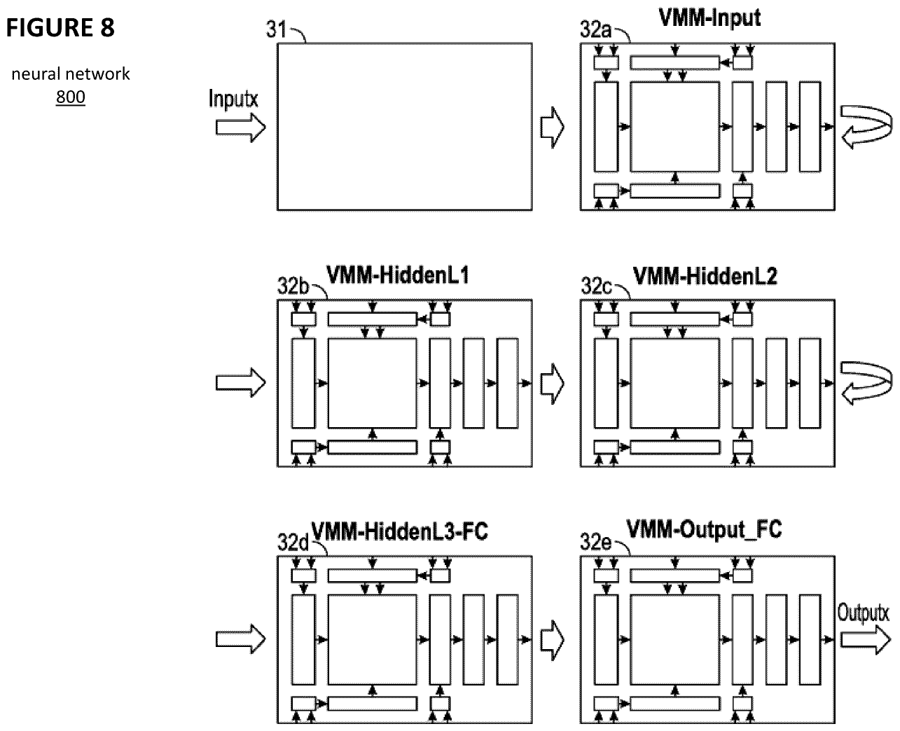

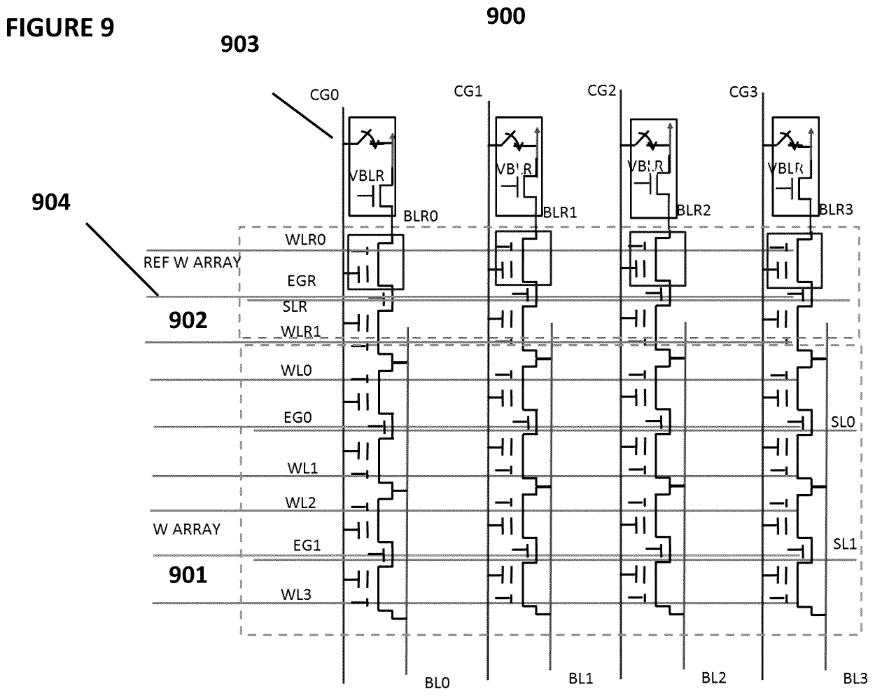

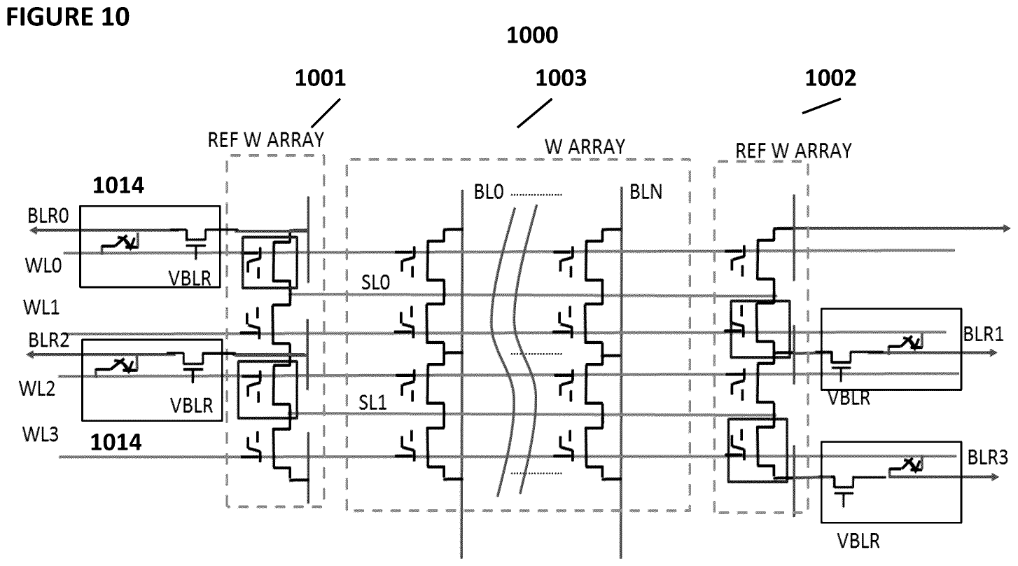

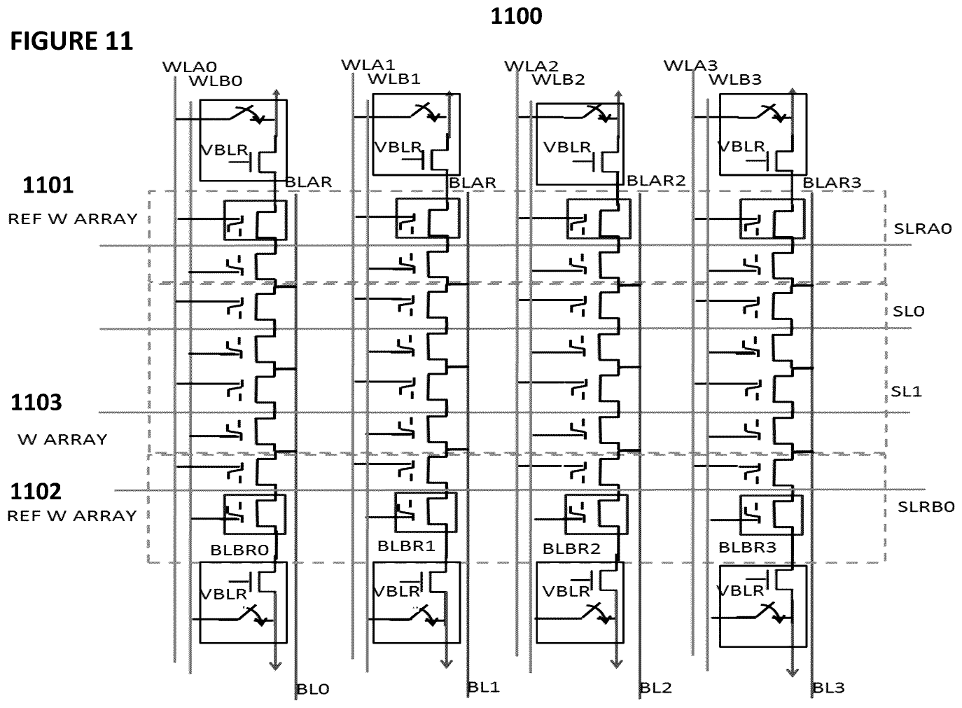

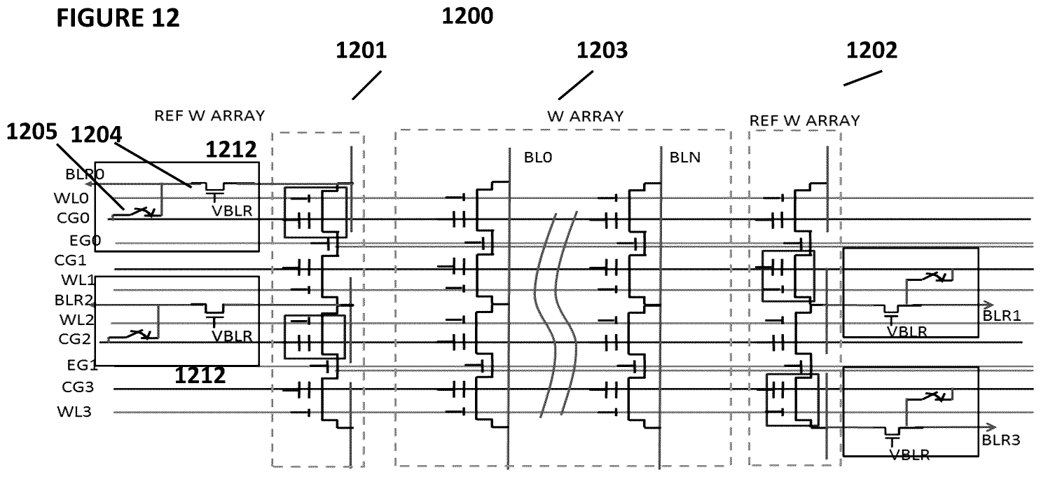

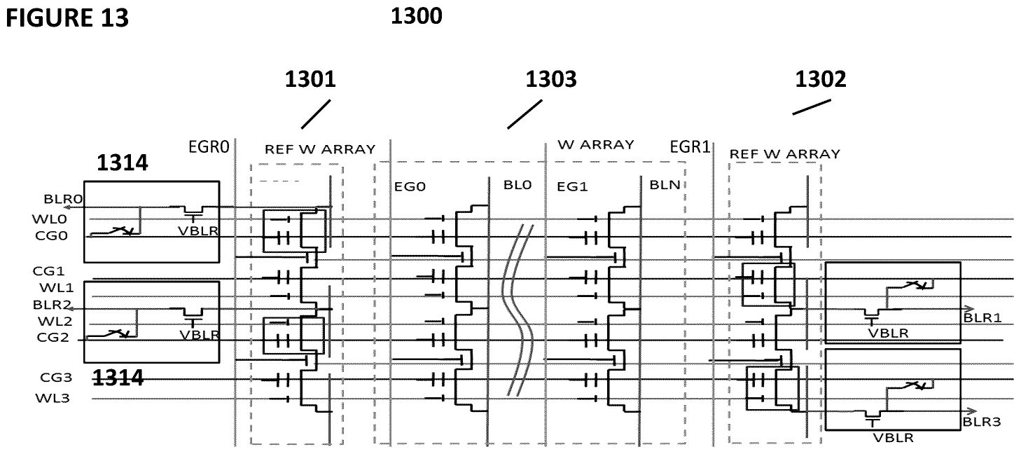

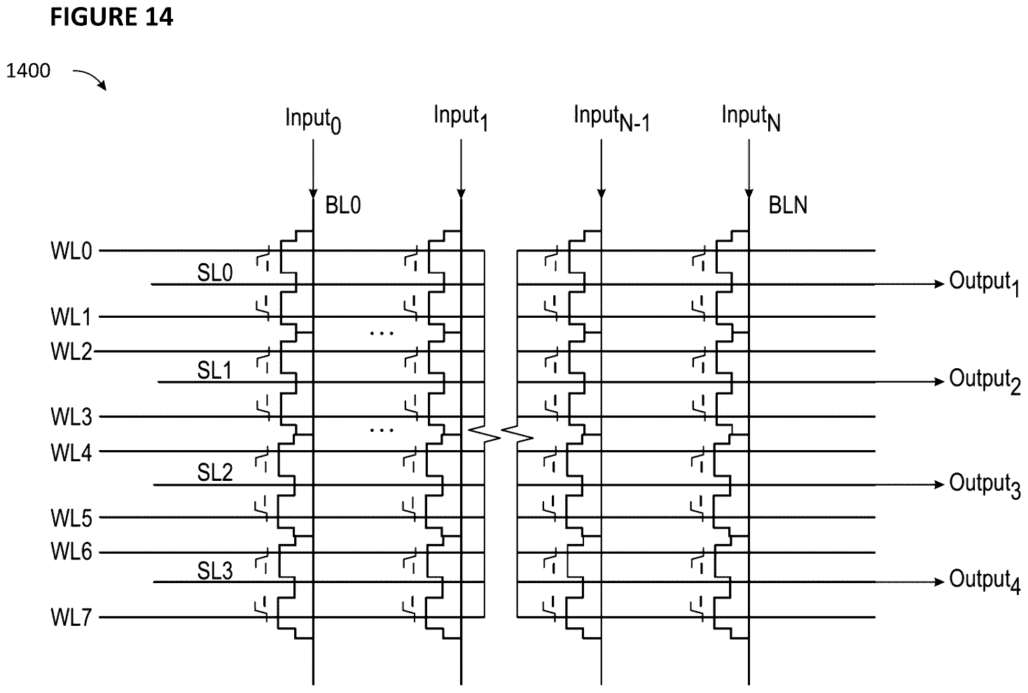

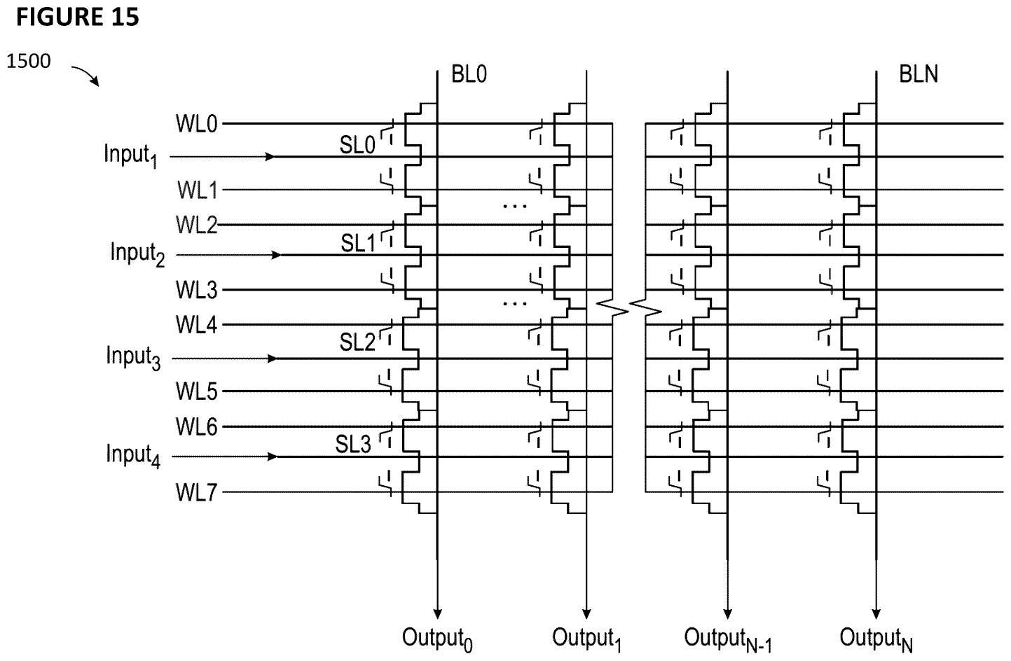

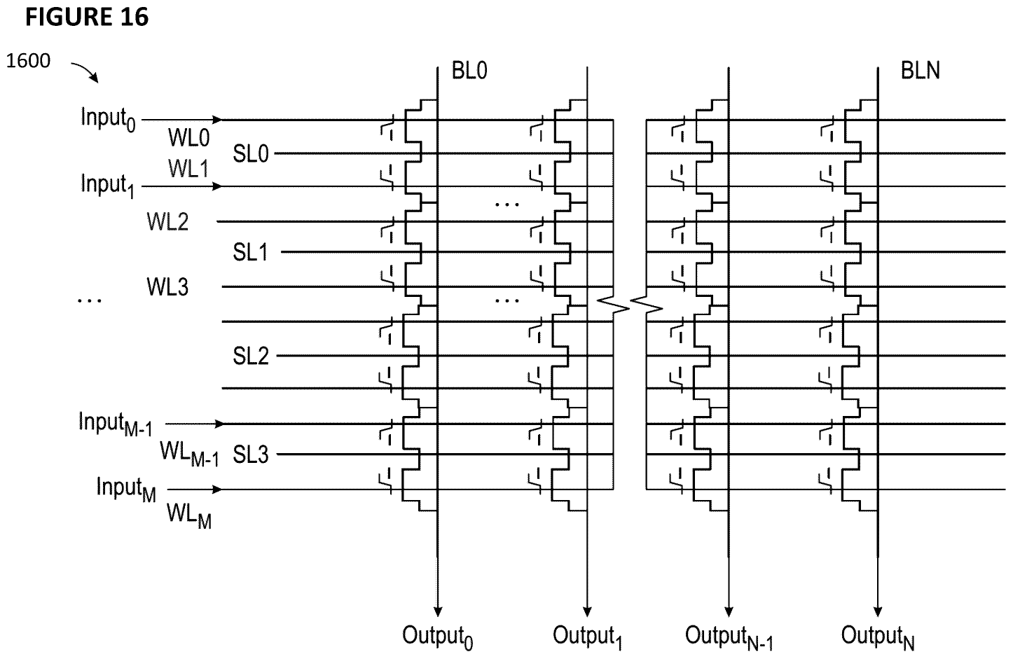

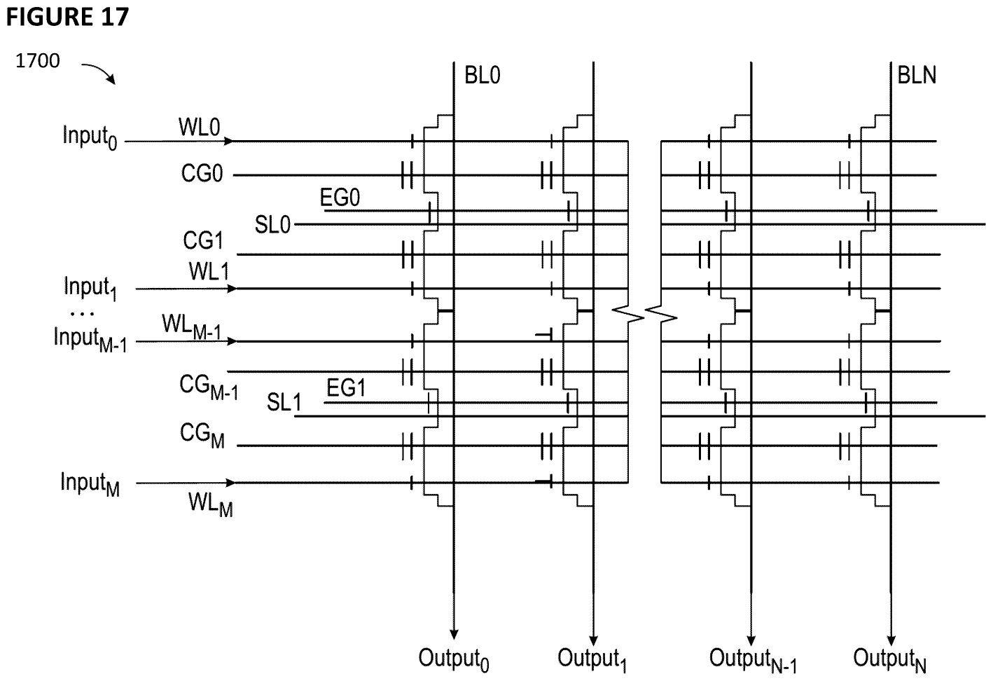

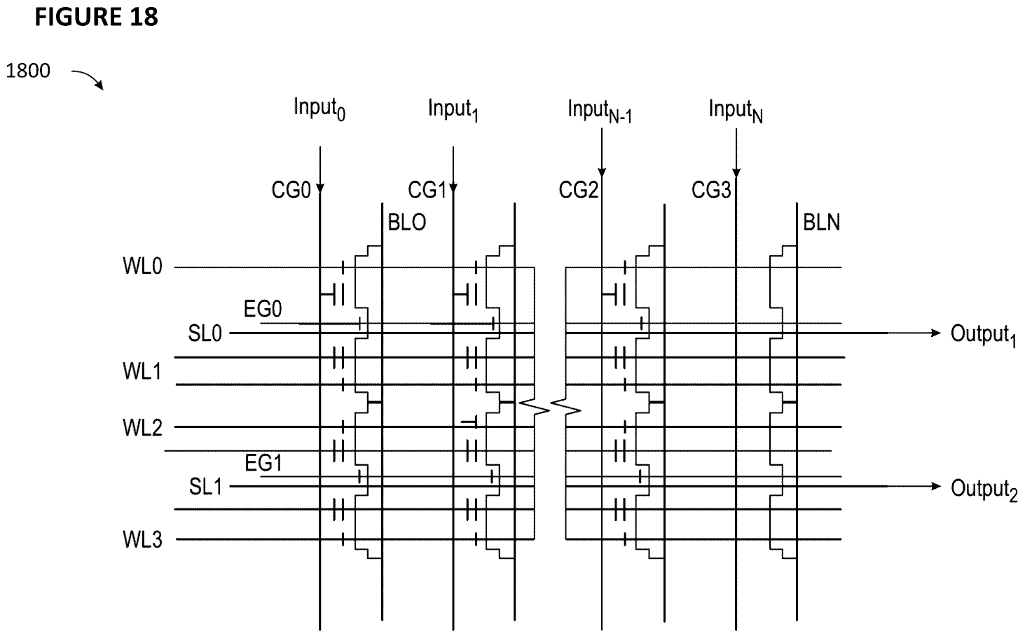

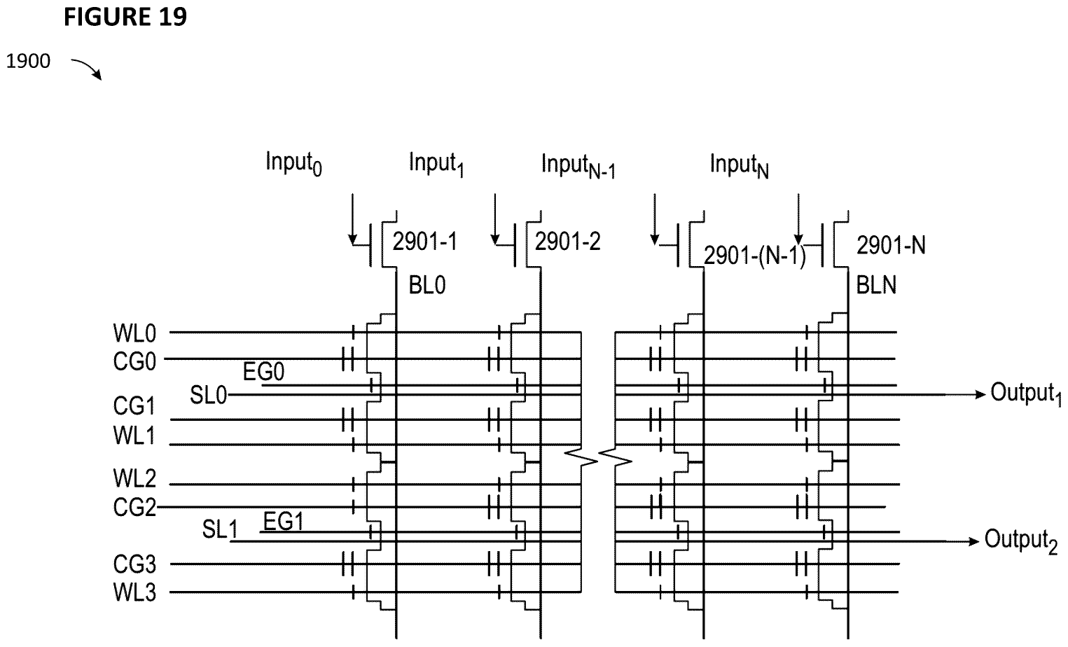

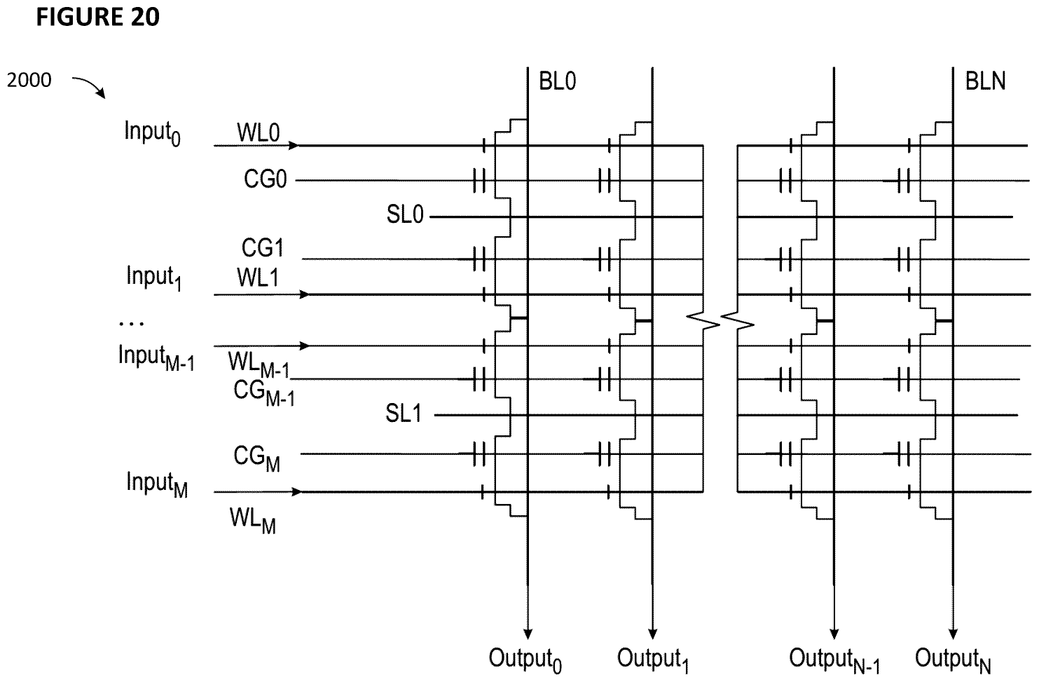

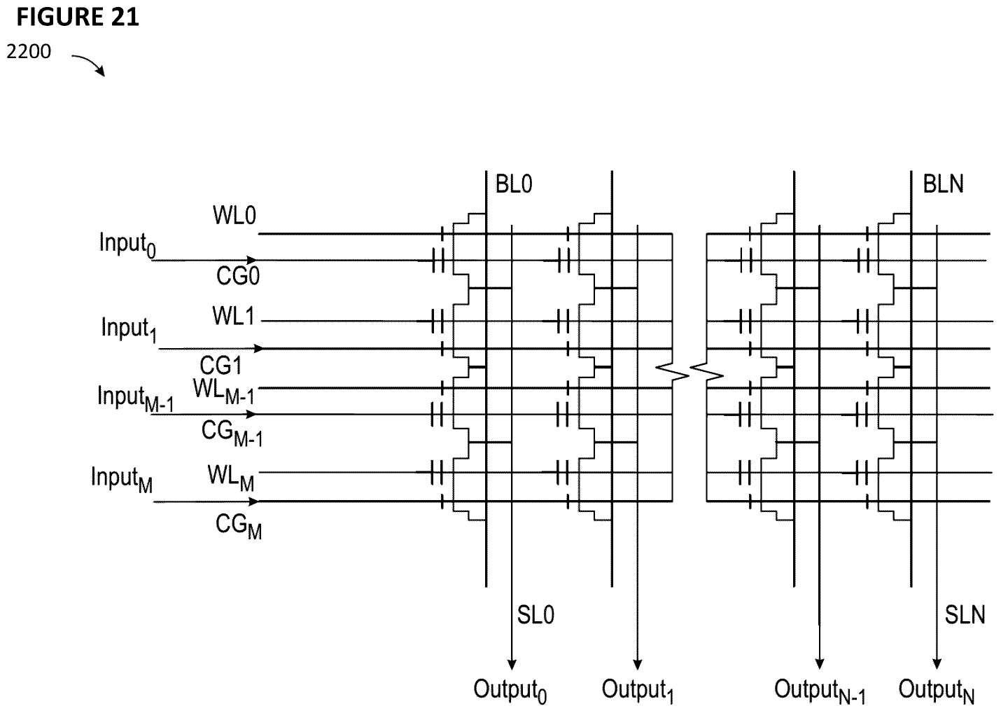

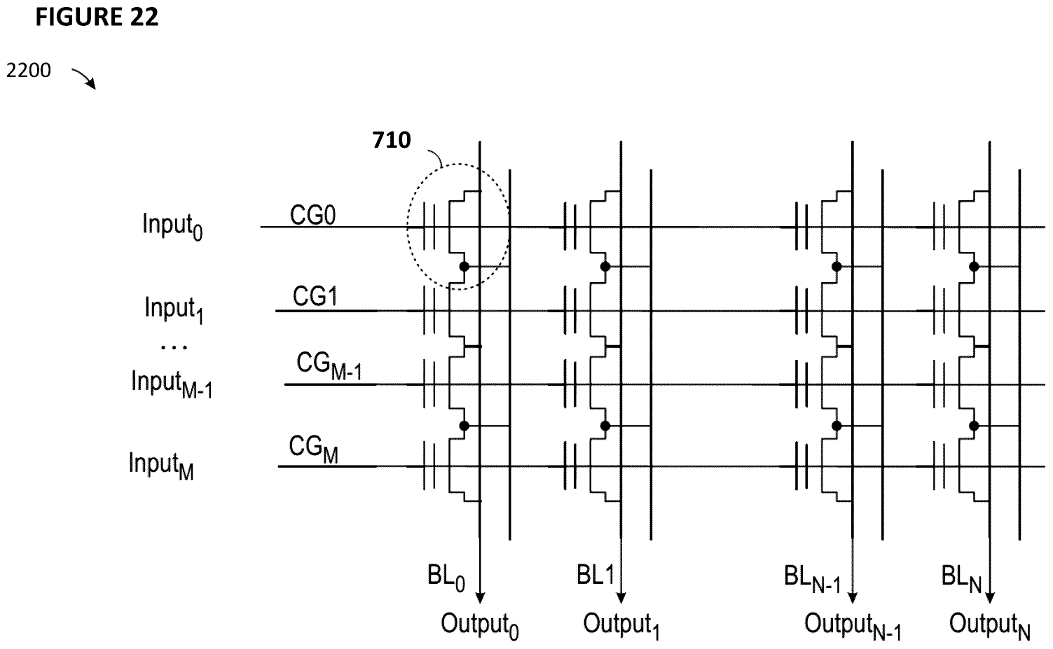

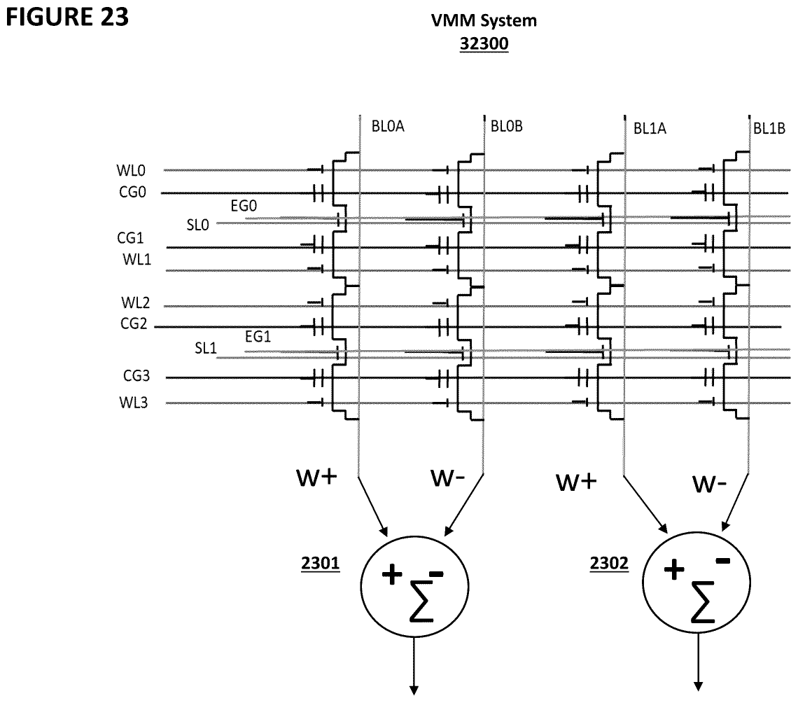

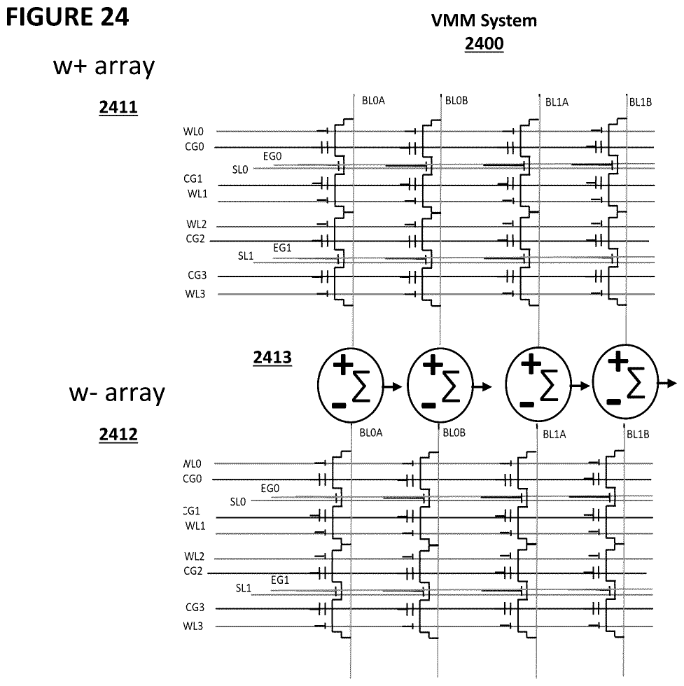

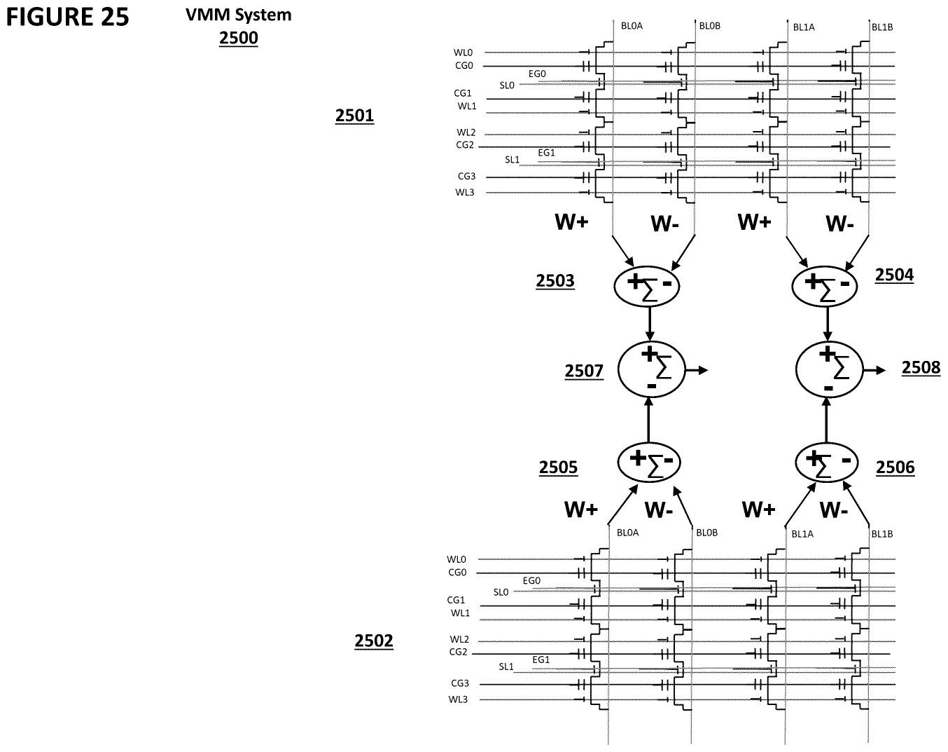

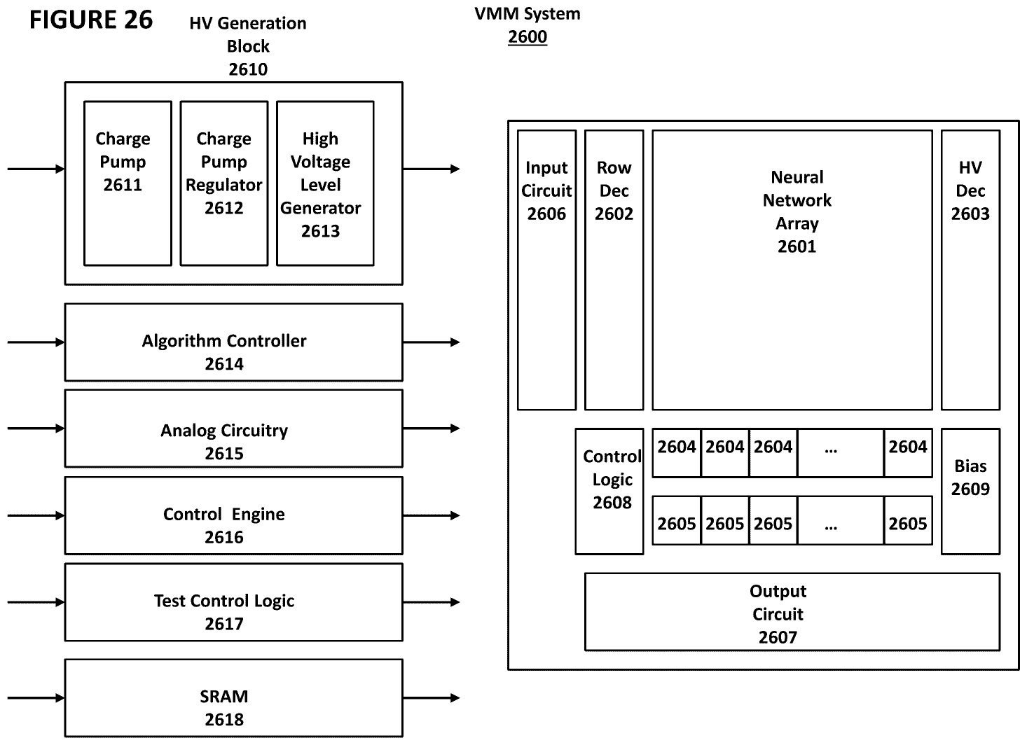

FIG. 26 depicts a block diagram of VMM system 2600. VMM system 2600 comprises neural network array 2601 (which is a VMM array), row decoder 2602, high voltage decoder 2603, column decoders 2604, bit line drivers 2605 (which can comprise bit line control circuitry for programming), input circuit 2606, output circuit 2607, control logic 2608, and bias generator 2609. VMM system 2600 further comprises high voltage generation block 2610, which comprises charge pump 2611, charge pump regulator 2612, and high voltage level generator 2613. VMM system 2600 further comprises (program/erase, or weight tuning) algorithm controller 2614, analog circuitry 2615, control engine 2616 (that may include functions such as arithmetic functions, activation functions, embedded microcontroller logic, without limitation), test control logic 2617, and static random access memory (SRAM) block 2618 to store intermediate data such as for input circuits (e.g., activation data) or output circuits (neuron output data, partial sum output neuron data) or data in for programming (such as data in for a whole row or for multiple rows). Neural network array 2601 comprises an array of non-volatile memory cells arranged into rows and columns, where the non-volatile memory cells are of the type shown in FIG. 2, 3, 4, or 5 as memory cells 210, 310, 410, or 510, respectively, or are of other types known to persons of ordinary skill in the art. In one example, the non-volatile memory cells are split-gate flash memory cells as in FIG. 2, 3, or 4. In another example, the non-volatile memory cells are stacked-gate flash memory cells as in FIG. 5.

The input circuit 2606 may include circuits such as a DAC (digital to analog converter), DPC (digital to pulses converter, digital to time modulated pulse converter), AAC (analog to analog converter, such as a current to voltage converter, logarithmic converter), PAC (pulse to analog level converter), or any other type of converter. The input circuit 2606 may implement one or more of normalization, linear or non-linear up/down scaling functions, or arithmetic functions. The input circuit 2606 may implement a temperature compensation function for input levels. The input circuit 2606 may implement an activation function such as a rectified linear activation function (ReLU) or a sigmoid. Input circuit 2606 may store digital activation data to be applied as, or combined with, an input signal during a program or read operation. The digital activation data may be stored in registers. Input circuit 2606 may comprise circuits to drive the array terminals, such as CG, WL, EG, and SL lines, which may include sample-and-hold circuits and buffers. A DAC can be used to convert digital activation data into an analog input voltage to be applied to the array.

The output circuit 2607 may include circuits such as an ITV (current-to-voltage circuit), ADC (analog to digital converter, to convert neuron analog output to digital bits), AAC (analog to analog converter, such as a current to voltage converter, logarithmic converter), APC (analog to pulse(s) converter, analog to time modulated pulse converter), or any other type of converter. The output circuit 2607 may convert array outputs into activation data. The output circuit 2607 may implement an activation function such as an ReLU or sigmoid. The output circuit 2607 may implement one or more of statistic normalization, regularization, up/down scaling/gain functions, statistical rounding, or arithmetic function (e.g., add, subtract, divide, multiply, shift, log) for neuron outputs. The output circuit 2607 may implement a temperature compensation function for neuron outputs or array outputs (such as bitline output) so as to keep power consumption of the array approximately constant over temperature or to improve precision of the array (neuron) outputs such as by keeping the IV slope approximately the same over temperature. The output circuit 2607 may comprise registers for storing output data.

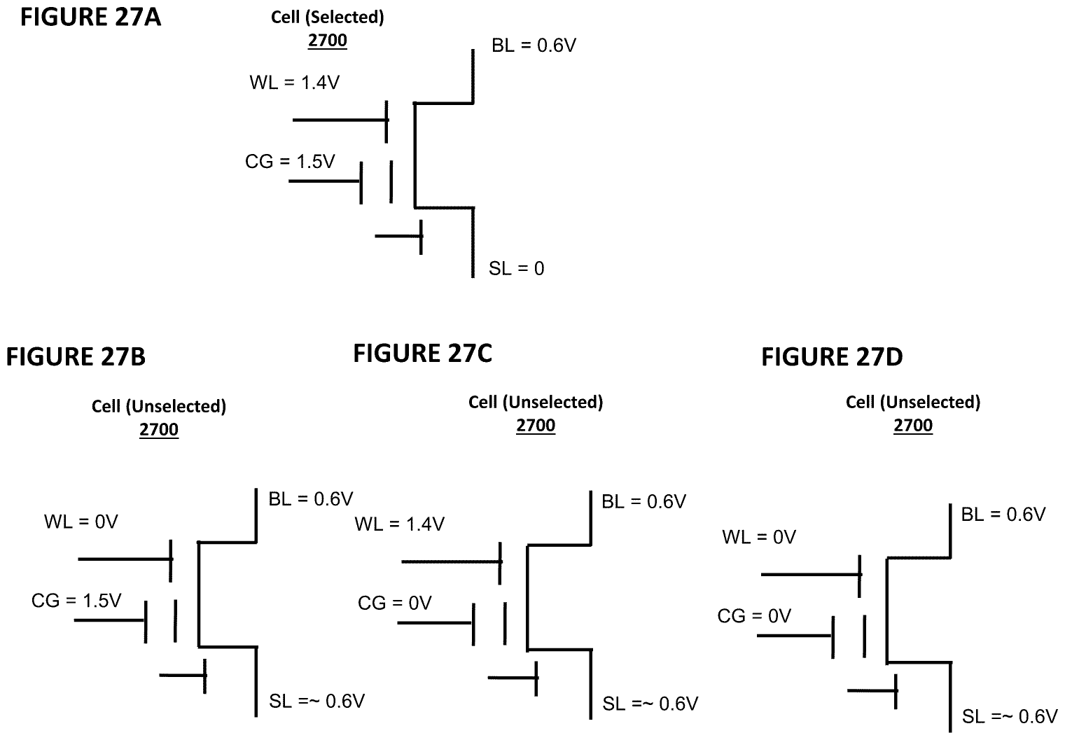

FIG. 27A depicts memory cell 2700 with examples of voltages that are applied when memory cell 2700 is selected for a read operation. In this example, 0.6 V is applied to memory cell 2700's bitline terminal, 1.4 V to its word line terminal, 1.5 V to its control gate terminal, and 0 V to its source line terminal.

FIGS. 27B, 27C, and 27D depict memory cell 2700 in three separate situations where it is unselected for a read operation, meaning that memory cell 2700 is not intended to be read and is not intended to contribute to the read current in a bitline.

In the example of FIG. 27B, 0.6 V is applied to the bitline terminal, 0 V to the word line terminal, and 1.5 V to the control gate terminal. In the example of FIG. 27C, 0.6 V is applied to the bitline terminal, 1.4 V to the word line terminal, and 0 V to the control gate terminal. In the example of FIG. 27D, 0.6 V is applied to the bitline terminal, 0 V to the word line terminal, and 0 V to the control gate terminal. In all three examples, a voltage of around 0.6 V is applied to the source line terminal. The application of a voltage of around 0.6 V to the source line terminal of un-selected memory cell 2700 is an inhibit action to reduce leakage on the bitline of the un-selected cells. This is due to reserve bias the source of a transistor to reduce the equivalent gate to source voltage (vgs). That is, if the source line terminal instead was connected to ground (e.g., =0 V), leakage would occur through memory cell 2700 to the bit line. Applying a voltage of around 0.6 V to the source line terminals of some or all un-selected cells will reduce leakage in neural network array 2601 in FIG. 26 compared to a situation where the source line terminals are coupled to ground. Alternatively, the source lines of un-selected memory cells can be allowed to float or be biased at another voltage, e.g., >0.3V, to reduce or inhibit leakage.

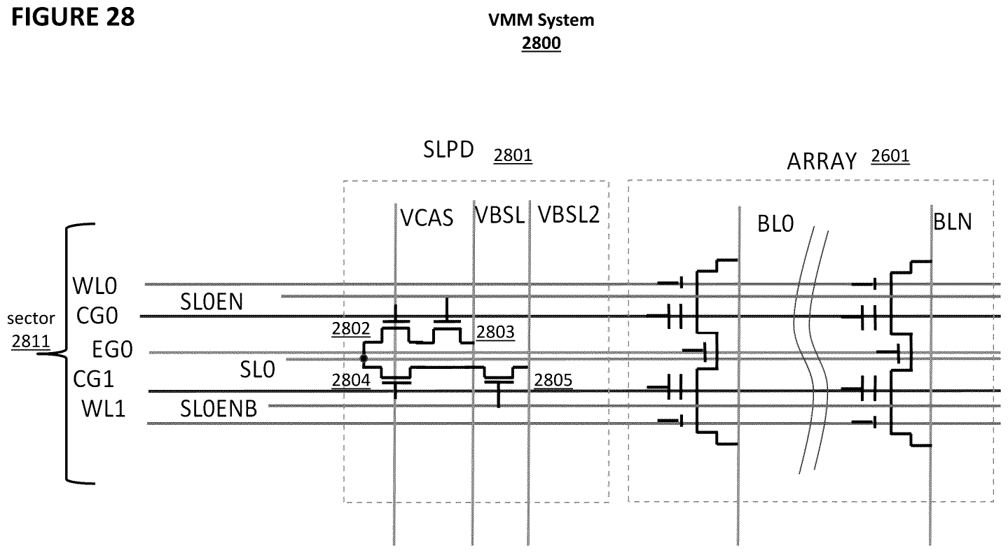

FIG. 28 depicts VMM system 2800. VMM system 2800 comprises array 2601 and source line pull down circuit (SLPN) 2801. Here, only two rows and two columns of cells are shown, but it is to be understood that array 2601 can comprise many more rows and many more columns. Here, a sector 2811 comprises two rows of cells in array 2601. Source line pull down circuit 2801 is provided on a per sector basis.

Source line pull down circuit 2801 comprises NMOS transistors 2802, 2803, 2804, and 2805. NMOS transistor 2803 comprises a first terminal coupled to a line VBSL (which contains a voltage as described below), a gate coupled to a signal line SL0EN (which is an enable signal to connect source line SL0 to VBSL and is generated as a result of a sector decode operation where the sector shown in FIG. 28 is either selected or not selected, such as by row decoder 2602 or the HV decoder 2603 in FIG. 26), and a second terminal. NMOS transistor 2802 comprises a first terminal coupled to the second terminal of NMOS transistor 2803, a gate coupled to a signal line VCAS (which is a voltage applied to reduce stress on NMOS transistors 2803 and 2805 when a high voltage is applied to source line SL0 during a programming operation), and a second terminal coupled to source line SL0. NMOS transistor 2804 comprises a first terminal coupled to the source line SL0, a gate coupled to the signal line VCAS, and a second terminal. NMOS transistor 2805 comprises a first terminal coupled to the second terminal of NMOS transistor 2804, a gate coupled to a signal line SL0ENB (which is the complement of SL0EN and is an enable signal to connect source line SL0 to VBSL2 and is generated as a result of a sector decode operation where the sector shown in FIG. 28 is either selected or not selected, such as by row decoder 2602 or the HV decoder 2603 in FIG. 26), and a second terminal coupled to a signal line VBSL2 (which contains a voltage as described below).

During a read or verify operation (regardless of whether sector 2811 is selected or not), VBSL receives from an external voltage source (not shown) a first voltage such as 0 V or 0.1 V (corresponding to the select operation shown in FIG. 27A), and VBLSL2 receives from an external voltage source (not shown) a second voltage such as around 0.6V (corresponding to the unselect operation shown in FIGS. 27B, 27C, and 27D to reduce or inhibit leakage). When sector 2811 is selected, SL0EN is asserted and SL0ENB is de-asserted, and source line SL0 is coupled to VBSL, meaning that SL0 receives the first voltage. When sector 2811 is unselected, SL0EN is de-asserted and SL0ENB is asserted, and source line SL0 is coupled to VBSL2, meaning that SL0 receives the second voltage.

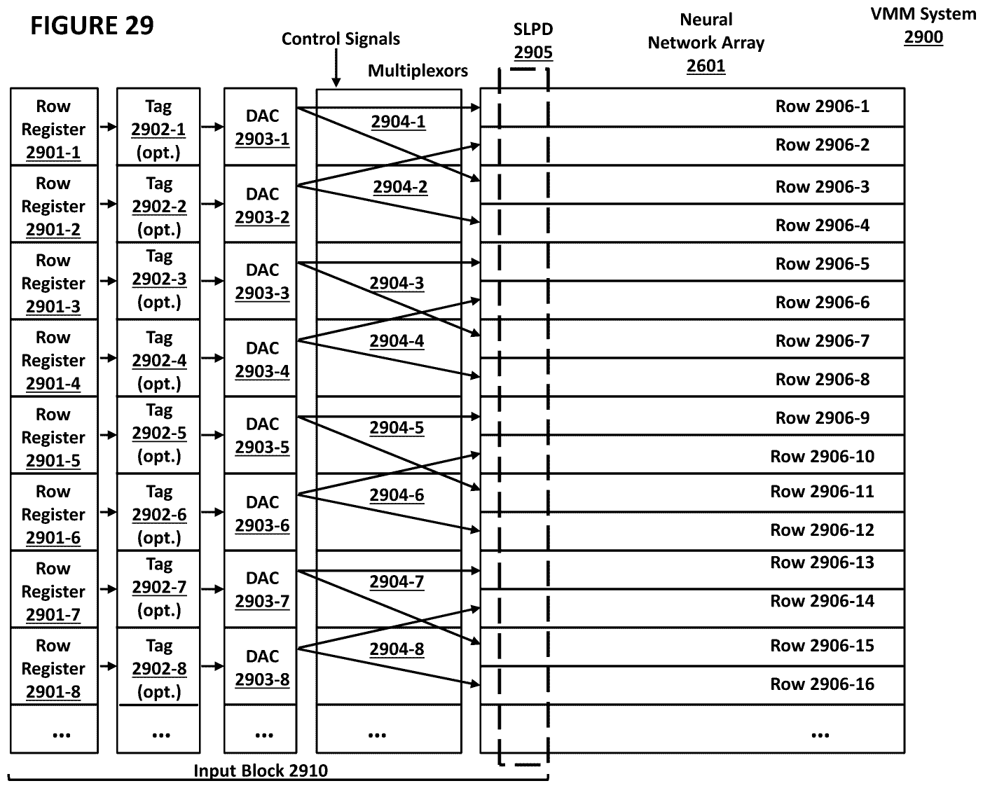

FIGS. 29-39 depict various input multiplexing schemes that can be used in VMM system 2600 to reduce the die space used for input circuit 2606 that provides inputs to neural network array 2601.

FIG. 29 depicts VMM system 2900, which comprises neural network array 2601 and input block 2910. Input block 2910 comprises row registers 2901-1 through 2901-8, row tag registers 2902-1 through 2902-8 (optional) containing row tag bits, digital to analog converters (DACs) 2903-1 through 2903-8 (or, alternatively, row sample and hold buffers (not shown)), multiplexors 2904-1 through 2904-8, and source line pull down circuit 2905 (which can comprise source line pull down circuit 2801 in FIG. 28 for each pair of consecutive rows or a comparable circuit). The use of row sample and hold buffers and row tag bits is described in U.S. patent application Ser. No. 18/077,686, filed on Dec. 8, 2022, and titled “Input Circuit for Artificial Neural Network Array,” which is incorporated by reference herein.

In one example, the DACs 2903 are n-bit analog DACs where n bits received from row register 2901 are converted into an analog signal that is applied to neural network array 2601. In another example, the DACs are 1-bit analog DAC where n bits received from row register 2901 are converted one bit at a time into an analog signal that is sequentially applied to neural network array 2601 in n separate operations and the resulting output from neural network array 2601 is summed together with output bit shifting performed. In another example, the DACs are pulse DACs where n bits received from register 2901 are converted into voltage pulses that are applied to neural network array 2601.

Neural network array 2601 comprises rows 2906-1 through 2906-16. Here, only 16 rows are shown in neural network array 2601, but it is to be understood that neural network array 2601 comprises i rows, where i can be a multiple of 2 and can be less than or more than 16. Similarly, only 8 row registers 2901, 8 tag registers 2902, 8 digital-to-analog converters 2903, and 8 multiplexors 2904 are shown, but it is to be understood that VMM system 2900 comprises j row registers 2901, j tag registers 2902, j digital-to-analog converters 2903, and j multiplexors 2904, where j<i. In the example shown, j=i/2.

In the prior art, there were i row registers and i digital-to-analog converters if the array contained i rows, meaning that each row had its own row register and digital-to-analog converter. In this example, there are i/2 row registers, i/2 row tag registers, i/2 digital-to-analog converters, i/2 source lines, and i/2 erase gate lines (that is, j=i/2), meaning that two rows share a row register, row tag register, digital-to-analog converter, source line, and erase gate line. The sharing of row registers, row tag registers, and digital-to-analog converters is enabled by the use of multiplexors 2904. In this example, respective multiplexors 2904 route an output of a digital-to-analog converter 2903 (or sample and hold buffer) to one of two rows in neural network array 2601. For example, multiplexor 2904-1 routes the output of digital-to-analog converter 2903-1 to row 2906-1 or row 2906-3 according to its control signal, and multiplexor 2904-2 routes the output of digital-to-analog converter 2903-2 to row 2906-2 or row 2906-4 according to its control signal, and so forth. Based on this routing structure, a sector can comprise a pair of consecutive rows, and the rows of a sector can be accessed concurrently as no consecutive rows share the same multiplexor although consecutive rows may share a source line and an erase gate line.

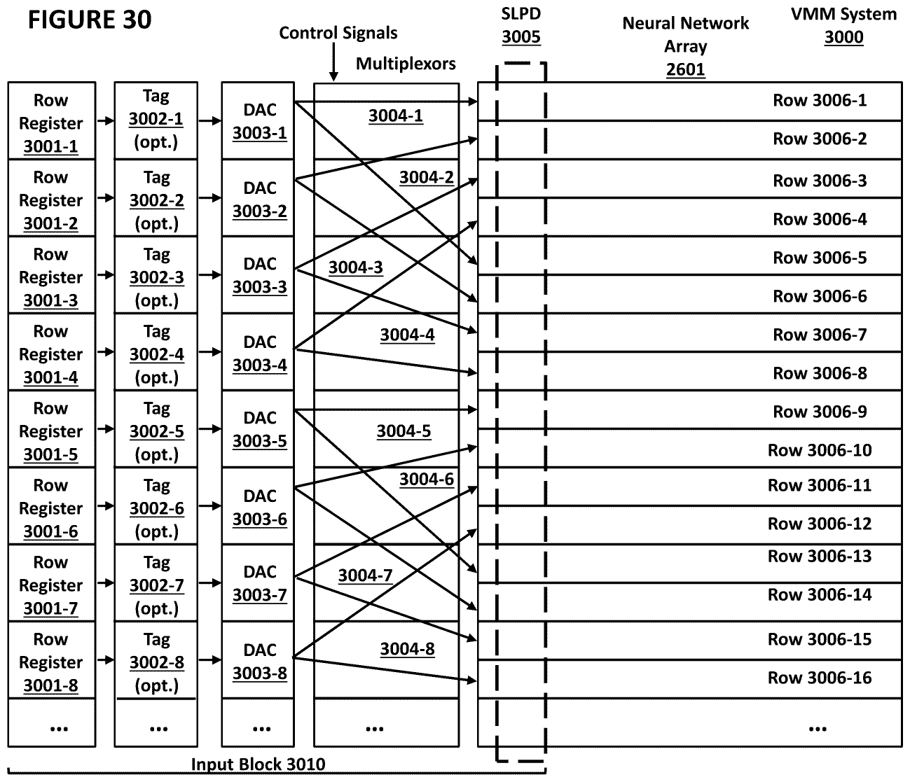

FIG. 30 depicts VMM system 3000, which comprises neural network array 2601 and input block 3010. Input block 3010 comprises row registers 3001-1 through 3001-8, row tag registers 3002-1 through 3002-8 (optional) containing row tag bits, digital to analog converters 3003-1 through 3003-8, multiplexors 3004-1 through 3004-8, and source line pull down circuit 3005 (which can comprise source line pull down circuit 2801 in FIG. 28 for each pair of consecutive rows or a comparable circuit). Neural network array 2601 comprises rows 3006-1 through 3006-16. Here, only 16 rows are shown in neural network array 2601, but it is to be understood that neural network array 2601 comprises i rows, where i can be a multiple of 2 and can be less than or greater than 16. Similarly, only 8 row registers 3001, 8 row tag registers 3002, 8 digital-to-analog converters 3003, and 8 multiplexors 3004 are shown, but it is to be understood that VMM system 3000 comprises j row registers 3001, j row tag registers 3002, j digital-to-analog converters 3003, and j multiplexors 3004, where j<i. In the example shown, j=i/2.

In this example, there are i/2 row registers, i/2 row tag registers, i/2 digital-to-analog converters, i/2 source lines, and i/2 erase gate lines (that is, j=i/2), meaning that two rows share a row register, row tag register, digital-to-analog converter, source line, and erase gate line. The sharing of row registers, row tag registers, and digital-to-analog converters is enabled by the use of multiplexors 3004. In this example, a multiplexor 3004 routes an output of a digital-to-analog converter 3003 to one of two rows in neural network array 2601. For example, multiplexor 3004-1 routes the output of digital-to-analog converter 3003-1 to row 3006-1 or row 3006-5 according to its control signal, and multiplexor 3004-2 routes the output of digital-to-analog converter 3003-2 to row 3006-2 or row 3006-6 according to its control signal, and so forth. In one example, a sector comprises consecutive rows. In another example, a sector comprises four consecutive rows. In either case, all rows in a sector can be accessed concurrently as no group of two or four consecutive rows share the same multiplexor 3004.

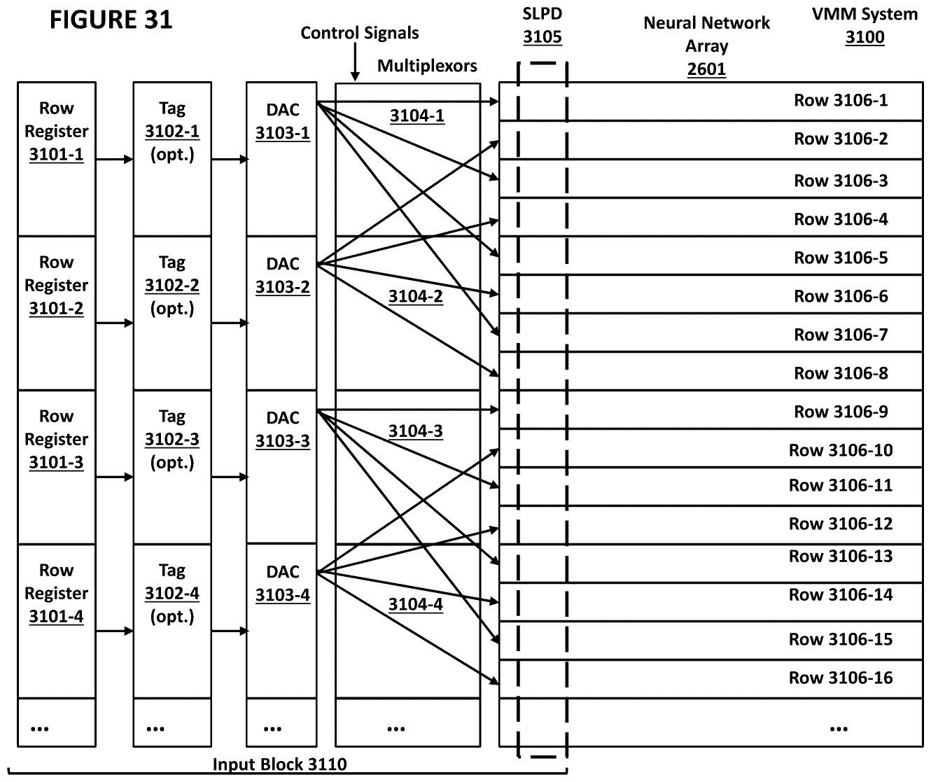

FIG. 31 depicts VMM system 3100, which comprises neural network array 2601 and input block 3110. Input block 3110 comprises row registers 3101-1 through 3101-4, row tag registers 3102-1 through 3102-4 (optional) containing row tag bits, digital to analog converters 3103-1 through 3103-4, multiplexors 3104-1 through 3104-4, and source line pull down circuit 3105 (which can comprise source line pull down circuit 2801 in FIG. 28 for each pair of consecutive rows or a comparable circuit). Neural network array 2601 comprises rows 3106-1 through 3106-16. Here, only 16 rows are shown in neural network array 2601, but it is to be understood that neural network array 2601 comprises i rows, where i can be a multiple of 2 and can be less than or greater than 16. Similarly, only 4 row registers 3101, 4 row tag registers 3102, 4 digital-to-analog converters 3103, and 4 multiplexors 3104 are shown, but it is to be understood that VMM system 3100 comprises j row registers 3101, j row tag registers 3102, j digital-to-analog converters 3103, and j multiplexors 3104, where j<i. In the example shown, j=i/4.

In this example, there are i/4 row registers, i/4 row tag registers, i/4 digital-to-analog converters (that is, j=i/4), i/2 source lines, and i/2 erase gate lines meaning that four rows share a row register, a row tag register, and a digital-to-analog converter, with 2 source lines and 2 erase gate lines used by the group of four rows. The sharing of row registers, row tag registers, and digital-to-analog converters is enabled by the use of multiplexors 3104. In this example, a multiplexor 3104 routes an output of a digital-to-analog converter 3103 to one of four rows in neural network array 2601. For example, multiplexor 3104-1 routes the output of digital-to-analog converter 3103-1 to rows 3106-1, 3106-3, 3106-5, or 3106-7 according to its control signal, multiplexor 3104-2 routes the output of digital-to-analog converter 3103-2 to rows 3106-2, 3106-4, 3106-6, or 3106-8 according to its control signal, and so forth. Based on this routing structure, the rows in a sector that is formed of two consecutive rows can be accessed concurrently as no two consecutive rows share the same multiplexor.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A system comprising:
a neural network array of non-volatile memory cells comprising i rows, where i is a multiple of 2;
j row registers, where j<i;
j digital-to-analog converters to convert j sets of digital data received from the j row registers into respective j analog signals; and
j multiplexors to route the respective j analog signals to a subset of the i rows in response to control signals.

2. The system of claim 1, wherein j=i/2.

3. The system of claim 1, wherein j=i/4.

4. The system of claim 1, comprising:
a source line pull down circuitry to pull a source line of a respective row of the array of non-volatile memory cells to a first voltage when the respective row of the array of non-volatile memory cells coupled to the source line are selected during a read or verify operation and to a second voltage when the respective row of the array of non-volatile memory cells coupled to the source line are unselected during a read or verify operation.

5. The system of claim 1, wherein the non-volatile memory cells are stacked-gate flash memory cells.

6. The system of claim 1, wherein the non-volatile memory cells are split-gate flash memory cells.

7. A method comprising:
converting, by j digital-to-analog converters, j sets of digital data received from j row registers into j analog signals; and
routing, by j multiplexors, the j analog signals to a subset of rows within i rows in a neural network array of non-volatile memory cells, where i is a multiple of 2 and j<i.

8. The method of claim 7, wherein j=i/2.

9. The method of claim 7, wherein j=i/4.

10. The method of claim 7, comprising:
pulling a source line to a first voltage when one or more rows coupled to the source line are selected during a read or verify operation.

11. The method of claim 10, comprising:
pulling the source line to a second voltage when the one or more rows coupled to the source line are unselected during a read or verify operation.

12. The method of claim 7, wherein the non-volatile memory cells are stacked-gate flash memory cells.

13. The method of claim 7, wherein the non-volatile memory cells are split-gate flash memory cells.

14. A system comprising:
a neural network array of non-volatile memory cells comprising i rows, where i is a multiple of 2;
i/2 source lines, where respective ones of said source lines are shared by a sector comprising two of the i rows; and
a circuit to couple respective ones of the i/2 source lines to a first voltage when one or more rows coupled to the respective source line are selected during a read or verify operation and to a second voltage when two rows coupled to the respective source line are unselected during a read or verify operation.

15. The system of claim 14, wherein the non-volatile memory cells are stacked-gate flash memory cells.

16. The system of claim 14, wherein the non-volatile memory cells are split-gate flash memory cells.

17. The system of claim 14, comprising:
j row registers, where j<i;
j digital-to-analog converters to convert j sets of digital data received from the j row registers into j analog signals; and
j multiplexors to route the j analog signals to a subset of the i rows in response to a control signal during a read or verify operation.

18. The system of claim 17, wherein j=i/2.

19. The system of claim 17, wherein j=i/4.

20. The system of claim 14, comprising:
i/2 erase gate lines, where respective ones of said i/2 erase gate lines are shared by a sector.
